(19) United States
(12) Patent Application Publication
(10) Pub. No.: US 2022/0359706 A1
(43) Pub. Date: Nov. 10, 2022

(54) SEMICONDUCTOR DEVICE AND METHOD OF MANUFACTURING SEMICONDUCTOR DEVICE

(71) Applicant: SONY SEMICONDUCTOR SOLUTIONS CORPORATION, KANAGAWA (JP)

(72) Inventors: TAKASHI FUTATSUKI, KUMAMOTO (JP); KENJI NAGAI, KUMAMOTO (JP); TAKASHI KAMIIRISA, KUMAMOTO (JP)

(21) Appl. No.: 17/618,656

(22) PCT Filed: Jun. 9, 2020
(86) PCT No.: PCT/JP2020/022738

§ 371 Date: Dec. 13, 2021

(30) Foreign Application Priority Data
Jun. 20, 2019 (JP) 2019-114339

(51) Int. Cl. H01L 29/49; H01L 23/66; H01L 27/12; H01L 29/417; H01L 29/78; H01L 29/40; H01L 21/84

(52) U.S. Cl. CPC H01L 29/4991; H01L 23/66; H01L 27/1203; H01L 29/41758; H01L 29/7838; H01L 29/401; H01L 21/84

(57) ABSTRACT

A semiconductor device according to one embodiment of the present disclosure includes: a first low-permittivity region provided in a region that is between first metals in an in-plane direction of a semiconductor layer and below a lower surface of the first metal in a stacking direction of the semiconductor layer; and a second low-permittivity region provided in a region that is between a contact plug and the gate electrode in the in-plane direction and below the first low-permittivity region in the stacking direction. A planar region of the second low-permittivity region is at least partially different from that of the first low-permittivity region.

### TECHNICAL FIELD

The present disclosure relates to a semiconductor device and a method of manufacturing a semiconductor device.

### BACKGROUND ART

The front-end of mobile communication terminals, such as mobile phones, is equipped with a radio-frequency switch (RF-SW) that handles radio-frequency (Radio Frequency: RF) electric signals.

In such a radio-frequency switch, in order to reduce the loss of electric signals passing therethrough, it is desired that resistance (also referred to as on-resistance) of a field-effect transistor (Field Effect Transistor: FET) in an on state and capacitance (also referred to as off-capacitance) of the FET in an off state be reduced. That is, in the radio-frequency switch, it is desired that the product of the on-resistance and the off-capacitance (Ron*Coff) be reduced, and various studies have been made (e.g., see PTL 1).

### CITATION LIST

### Patent Literature

PTL 1: Japanese Unexamined Patent Application Publication No. 2015-207640

### SUMMARY OF THE INVENTION

Therefore, in a semiconductor device, such as a field-effect transistor, to be used in a radio-frequency switch, it is desired that the product of on-resistance and off-capacitance be reduces.

Hence, it is desirable to provide a semiconductor device that makes it possible to further reduce off-capacitance, and a method of manufacturing the semiconductor device.

A semiconductor device according to one embodiment of the present disclosure includes: a gate electrode; a semiconductor layer including a source region and a drain region provided with the gate electrode in between; contact plugs provided on the source region and the drain region; first metals stacked on the respective contact plugs; a first low-permittivity region provided in at least any region that is between the first metals in an in-plane direction of the semiconductor layer and below a lower surface of the first metal in a stacking direction of the semiconductor layer; and a second low-permittivity region provided in at least any region that is between the contact plug and the gate electrode in the in-plane direction and below the first low-permittivity region in the stacking direction. The second low-permittivity region is provided in a planar region that is at least partially different from a planar region provided with the first low-permittivity region.

A method of manufacturing a semiconductor device according to one embodiment of the present disclosure includes: a step of forming a gate electrode on an upper surface side of a semiconductor layer; a step of forming, in the semiconductor layer, a source region and a drain region with the gate electrode in between; a step of forming contact plugs on the source region and the drain region; a step of stacking first metals on the respective contact plugs; a step of forming a first low-permittivity region in at least any region that is between the first metals in an in-plane direction of the semiconductor layer and below a lower surface of the first metal in a stacking direction of the semiconductor layer; and a step of forming a second low-permittivity region in at least any region that is between the contact plug and the gate electrode in the in-plane direction and below the first low-permittivity region in the stacking direction. The second low-permittivity region is formed in a planar region that is at least partially different from a planar region in which the first low-permittivity region is formed.

In the semiconductor device and the method of manufacturing the semiconductor device according to one embodiment of the present disclosure, the first low-permittivity region is provided in at least any region that is between the first metals in the in-plane direction of the semiconductor layer and below a lower surface of the first metal in the stacking direction of the semiconductor layer, and the second low-permittivity region is provided in at least any region that is between the contact plug and the gate electrode in the in-plane direction and below the first low-permittivity region in the stacking direction. This makes it possible to reduce the permittivity of a space between the contact plug and the gate electrode.

### BRIEF DESCRIPTION OF DRAWINGS

FIG. 1 is a schematic diagram illustrating a configuration of a radio-frequency switch in which the number of input/output ports is one-to-ten.

FIG. 2 is a schematic diagram illustrating a configuration of a radio-frequency switch in which the number of input/output ports is one-to-one.

FIG. 3 is a circuit diagram illustrating an equivalent circuit of the radio-frequency switch illustrated in FIG. 2.

FIG. 4 is a circuit diagram illustrating the equivalent circuit in a case where the radio-frequency switch illustrated in FIG. 2 is in an on state.

FIG. 5 is a circuit diagram illustrating the equivalent circuit in a case where the radio-frequency switch illustrated in FIG. 2 is in an off state.

FIG. 6 is a plan view of an overall configuration of a semiconductor device according to a first embodiment of the present disclosure.

FIG. 7 is a longitudinal cross-sectional view of a cross-sectional configuration, along line VII-VII in FIG. 6, of the semiconductor device according to the embodiment.

FIG. 8 is a schematic longitudinal cross-sectional view of off-capacitance, divided into elements, of a typical field-effect transistor.

FIG. 9 is a longitudinal cross-sectional view of a stacked structure of a semiconductor device according to a comparative example.

FIG. 10 is a graph illustrating results of simulating the magnitudes of extrinsic components Cex of the semiconductor device illustrated in FIG. 7 and the semiconductor device according to the comparative example illustrated in FIG. 9.

FIG. 11 is a schematic diagram illustrating the positional relationship, in a Z stacking direction, between a first low-permittivity region and a second low-permittivity region and a multilayer wiring part in the semiconductor device illustrated in FIG. 7.

FIG. 12 is a schematic diagram illustrating the positional relationship, in a XY in-plane direction, between the first low-permittivity region and the second low-permittivity region and the multilayer wiring part in the semiconductor device illustrated in FIG. 7.

FIG. 13 is a longitudinal cross-sectional view of a cross-sectional configuration along line XV-XV in FIG. 12.

FIG. 14 is a longitudinal cross-sectional view of a cross-sectional configuration along line XVIA-XVIB in FIG. 12.

FIG. 15 is a longitudinal cross-sectional view of a cross-sectional configuration along line XVIIB-XVIIC in FIG. 12.

FIG. 16 is a longitudinal cross-sectional view of a cross-sectional configuration along line XVIIIC-XVIIID in FIG. 12.

FIG. 17 is a longitudinal cross-sectional view of a step of manufacturing the semiconductor device according to the embodiment.

FIG. 18 is a longitudinal cross-sectional view of a step of manufacturing the semiconductor device according to the embodiment.

FIG. 19 is a longitudinal cross-sectional view of a step of manufacturing the semiconductor device according to the embodiment.

FIG. 20 is a longitudinal cross-sectional view of a step of manufacturing the semiconductor device according to the embodiment.

FIG. 21 is a longitudinal cross-sectional view of a step of manufacturing the semiconductor device according to the embodiment.

FIG. 22 is a longitudinal cross-sectional view of a step of manufacturing the semiconductor device according to the embodiment.

FIG. 23 is a longitudinal cross-sectional view of a step of manufacturing the semiconductor device according to the embodiment.

FIG. 24 is a longitudinal cross-sectional view of a step of manufacturing the semiconductor device according to the embodiment.

FIG. 25 is a longitudinal cross-sectional view of a step of manufacturing the semiconductor device according to the embodiment.

FIG. 26 is a longitudinal cross-sectional view of a step of manufacturing the semiconductor device according to the embodiment.

FIG. 27 is a longitudinal cross-sectional view of a step of manufacturing the semiconductor device according to the embodiment.

FIG. 28 is a longitudinal cross-sectional view of a step of manufacturing the semiconductor device according to the embodiment.

FIG. 29 is a longitudinal cross-sectional view of a step of manufacturing the semiconductor device according to the embodiment.

FIG. 30 is a longitudinal cross-sectional view of a cross-sectional configuration of a semiconductor device according to a second embodiment of the present disclosure.

FIG. 31 is a longitudinal cross-sectional view of a cross-sectional configuration of a semiconductor device according to a third embodiment of the present disclosure.

FIG. 32 is a longitudinal cross-sectional view of a cross-sectional configuration of a semiconductor device according to a fourth embodiment of the present disclosure.

FIG. 33 is a longitudinal cross-sectional view of a cross-sectional configuration of a semiconductor device according to a fifth embodiment of the present disclosure.

FIG. 34 is a longitudinal cross-sectional view of a cross-sectional configuration of a semiconductor device according to a sixth embodiment of the present disclosure.

FIG. 35 is a longitudinal cross-sectional view of a cross-sectional configuration of a semiconductor device according to a seventh embodiment of the present disclosure.

FIG. 36 is a schematic diagram illustrating an example of a configuration of a wireless communication apparatus to which the semiconductor devices according to the first to seventh embodiments of the present disclosure are applied.

### MODES FOR CARRYING OUT THE INVENTION

In the following, description is given of embodiments of the present disclosure in detail with reference to the drawings. The embodiments described below are specific examples of the present disclosure, and the technology according to the present disclosure should not be limited to the following embodiments. Further, arrangements, dimensions, dimensional ratios, and the like of each component illustrated in the drawings of the present disclosure are not limited to those illustrated in the drawings.

It is to be noted that the description is given in the following order.
1. First Embodiment
1.1. Configuration of Radio-Frequency Switch
1.2. Configuration of Semiconductor Device
1.3. Method of Manufacturing Semiconductor Device
2. Second Embodiment
3. Third Embodiment
4. Fourth Embodiment
5. Fifth Embodiment
6. Sixth Embodiment
7. Seventh Embodiment
8. Application Example

### 1. First Embodiment

(1.1. Configuration of Radio-Frequency Switch)

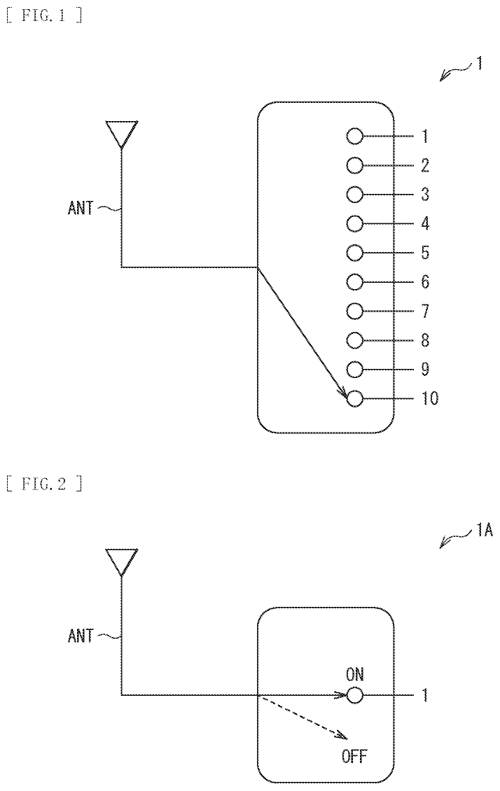

First, referring to FIGS. 1 to 5, a configuration of a radio-frequency switch including a semiconductor device according to a first embodiment of the present disclosure will be described. FIG. 1 is a schematic diagram illustrating a configuration of a radio-frequency switch in which the number of input/output ports is one-to-ten, and FIG. 2 is a schematic diagram illustrating a configuration of a radio-frequency switch in which the number of input/output ports is one-to-one.

A radio-frequency switch is an electronic component mainly used for signal processing in a radio frequency (Radio Frequency: RF) band. For example, the radio-frequency switch is used in the front-end or the like of a mobile information terminal, such as a mobile phone. The radio-frequency switch may take various configurations, such as SPST (Single Pole Single Throw: single pole single throw), SPDT (Single Pole Double Throw: single pole double throw), SP3T, . . . and SPNT (N is a real number), depending on the number of input/output ports.

For example, a radio-frequency switch 1 illustrated in FIG. 1 is an example of a SP10T switch. The radio-frequency switch 1, which is a SP10T switch, includes one pole coupled to an antenna ANT and ten contacts, for example, and is able to control the contact to be coupled from among the ten contacts. Further, a radio-frequency switch 1A illustrated in FIG. 2 is an example of a SPST switch. The radio-frequency switch 1A, which is a SPST switch, includes one pole coupled to an antenna ANT and one contact, for example, and is able to control the on/off of the one contact.

Note that the radio-frequency switch may also take a configuration other than the configurations illustrated in FIGS. 1 and 2. Specifically, the radio-frequency switch may take a variety of configurations by combining circuits of the SPST switch illustrated in FIG. 2.

Now, FIGS. 3 to 5 illustrate an equivalent circuit of the radio-frequency switch 1A illustrated in FIG. 2. FIG. 3 is a circuit diagram illustrating the equivalent circuit of the radio-frequency switch 1A illustrated in FIG. 2. FIG. 4 is a circuit diagram illustrating the equivalent circuit in a case where the radio-frequency switch 1A illustrated in FIG. 2 is in an on state, and FIG. 5 is a circuit diagram illustrating the equivalent circuit in a case where the radio-frequency switch 1A illustrated in FIG. 2 is in an off state.

As illustrated in FIG. 3, the radio-frequency switch 1A, which is a SPST, includes a first port Port1 coupled to the antenna ANT, a second port Port2 on the output side, a first switching device FET1, and a second switching device FET2, for example. The first switching device FET1 is provided between the first port Port1 and the ground, and the second switching device FET2 is provided between the first port Port1 and the second port Port2.

Such a radio-frequency switch 1A is able to control the on state or the off state of the switch by applying, via resistors, control voltages Vc1 and Vc2 to gates of the first switching device FET1 and the second switching device FET2.

When the radio-frequency switch 1A is in the on state, the second switching device FET2 is in a conductive state, and the first switching device FET1 is in a non-conductive state, as illustrated in FIG. 4. Further, when the radio-frequency switch 1A is in the off state, the first switching device FET1 is in the conductive state, and the second switching device FET2 is in the non-conductive state, as illustrated in FIG. 5.

The first switching device FET1 and the second switching device FET2 are equivalent to resistors in the conductive state, and are equivalent to capacitors in the non-conductive state. Therefore, in the first switching device FET1 and the second switching device FET2, resistance called on-resistance is generated in the conductive state, and capacitance called off-capacitance is generated in the non-conductive state.

Here, the on-resistances and the off-capacitances of the first switching device FET1 and the second switching device FET2 may be expressed respectively as Ron/Wg₁, Ron/Wg₂, Coff*Wg₁, and Coff*Wg₂ by using Ron [Ωmm] and Coff [fF/mm] per unit length of field-effect transistors and gate widths Wg₁ and Wg₂ [mm] of the field-effect transistors. That is, in the field-effect transistors, the on-resistance is inversely proportional to the gate widths Wg₁ and Wg₂, and the off-capacitance is proportional to the gate widths Wg₁ and Wg₂.

Therefore, in the field-effect transistor, in a case where the gate width Wg is increased to reduce loss due to the on-resistance, loss due to the off-capacitance increases. Further, although the on-resistance of the field-effect transistor does not depend on signal frequency, the off-capacitance increases as the signal frequency increases. Therefore, in the radio-frequency switch, which handles radio-frequency signals, the loss due to the off-capacitance further increases.

Therefore, in order to reduce the loss of the field-effect transistor to be used in the radio-frequency switch, it is important to reduce both Ron and Coff per unit length, that is, to reduce Ron*Coff (product).

The technology according to the present disclosure has been made in view of the above circumstances. The technology according to the present disclosure reduces parasitic capacitance of a semiconductor device, such as a field-effect transistor, thereby reducing on-resistance and off-capacitance of the field-effect transistor. The technology according to the present disclosure may be suitably used for a radio-frequency switch or the like to be provided in electronic equipment that handles radio-frequency signals.

(1.2. Configuration of Semiconductor Device)

Next, referring to FIGS. 6 and 7, a configuration of a semiconductor device according to a first embodiment of the present disclosure will be described. FIG. 6 is a plan view of the overall configuration of the semiconductor device according to the present embodiment.

As illustrated in FIG. 6, a semiconductor device 10 according to the present embodiment includes, for example, a gate electrode 20 provided on an unillustrated semiconductor layer, a source electrode 30S, and a drain electrode 30D. Note that the gate electrode 20 is hatched in FIG. 6.

The semiconductor device 10 is, for example, a field-effect transistor for a radio-frequency device, configuring the first switching device FET1 or the second switching device FET2 included in the radio-frequency switch 1A illustrated in FIG. 3.

The gate electrode 20 is provided with a multi-finger structure including a plurality of finger parts 21 extending in one direction and a linking part 22 linking the plurality of finger parts 21 to each other. In order to reduce loss, a gate-width Wg of the field-effect transistor to be used in the radio-frequency switch is larger than that of a field-effect transistor to be used in a logic circuit or the like, and is several hundred micrometers to several millimeters, for example. Further, a length (finger length) L21 of the finger part 21 is several tens of micrometers, for example. Note that the linking part 22 is coupled to an unillustrated gate contact.

In the following description, the direction in which the finger part 21 of the gate electrode 20 extends is referred to as a Y direction. Further, a direction orthogonal to the Y direction and in which the linking part 22 extends is referred to as an X direction. Furthermore, a direction orthogonal to both the X direction and the Y direction (i.e., a direction perpendicular to a plane of the unillustrated semiconductor layer) is referred to as a Z direction.

As with the gate electrode 20, the source electrode 30S includes finger parts 31S extending in one direction (e.g., the Y direction) and a linking part 32S linking the plurality of finger parts 31S and coupled to an unillustrated source contact.

As with the gate electrode 20, the drain electrode 30D includes finger parts 31D extending in one direction (e.g., the Y direction) and a linking part 32D linking the plurality of finger parts 31D and coupled to an unillustrated drain contact.

The finger part 21 of the gate electrode 20, the finger part 31S of the source electrode 30S, and the finger part 31D of the drain electrode 30D are disposed inside an active region AA activated by a conductivity-type impurity being introduced. Specifically, the finger part 31S of the source electrode 30S and the finger part 31D of the drain electrode 30D are alternately arranged between the finger parts 21 of the gate electrode 20. On the other hand, the linking part 22 of the gate electrode 20, the linking part 32S of the source electrode 30S, and the linking part 32D of the drain electrode 30D are disposed in a device isolation region (unillustrated) provided outside the active region AA.

Now, referring to FIG. 7, a cross-sectional configuration of the semiconductor device 10 according to the present embodiment will be described. FIG. 7 is a longitudinal cross-sectional view of the cross-sectional configuration along line VII-VII in FIG. 6. FIG. 7 illustrates the cross-sectional configuration including one of the finger parts 21 of the gate electrode 20, and the finger part 31S of the source electrode 30S and the finger part 31D of the drain electrode 30D disposed on both sides of the finger part 21.

As illustrated in FIG. 7, the semiconductor device 10 includes, for example, the gate electrode 20 described above, a semiconductor layer 50, contact plugs 60S and 60D, first metals M1 including the source electrode 30S and the drain electrode 30D described above, a first low-permittivity region 70, and a second low-permittivity region 71.

The gate electrode 20 is provided on the semiconductor layer 50 via a gate insulating film 23. The gate electrode 20 may include, for example, polysilicon with a thickness of 100 nm to 200 nm. The gate insulating film 23 may include, for example, silicon oxide (SiOₓ) with a thickness of 5 nm to 15 nm.

The semiconductor layer 50 may include, for example, a semiconductor such as silicon (Si). In the semiconductor layer 50, a source region 50S and a drain region 50D including first-conductivity-type (n+) silicon are provided on both sides across the gate electrode 20. Further, on the surface side of the source region 50S and the drain region 50D, low-resistance regions 51S and 51D including first-conductivity-type (n++) silicon with higher concentration or silicide are provided for connection to the contact plugs 60S and 60D. Furthermore, extension regions 52S and 52D including low-concentration first-conductivity-type (n−) silicon are provided between the source region 50S and the gate electrode 20 and between the drain region 50D and the gate electrode 20.

Here, the semiconductor layer 50 is provided on a support substrate 53 via a buried oxide film 54, for example. The support substrate 53 may include a high-resistance silicon (Si) substrate, for example, and the buried oxide film 54 may include silicon oxide (SiOₓ), for example. That is, the support substrate 53, the buried oxide film 54, and the semiconductor layer 50 may configure a so-called SOI (Silicon On Insulator) substrate 55.

Although a case where the support substrate 53 of the SOI substrate 55 is a high-resistance silicon substrate is described above, the technology according to the present disclosure is not limited to the above example. The support substrate 53 may be a sapphire substrate. In such a case, the SOI substrate 55 may configure a so-called SOS (Silicon On Sapphire) substrate. Because the sapphire substrate has an insulating property, a field-effect transistor formed on the SOS substrate exhibits characteristics closer to a compound (e.g., GaAs)-based field-effect transistor. Further, the technology according to the present disclosure is not limited to the case where the support substrate 53 is an SOI substrate or an SOS substrate, and is similarly applicable to a case where the support substrate 53 is a bulk silicon substrate.

The contact plugs 60S and 60D are provided on the low-resistance regions 51S and 51D on the surfaces of the source region 50S and the drain region 50D. The contact plugs 60S and 60D may be configured by, for example, stacking a titanium (Ti) layer, a titanium nitride (TiN) layer, and a tungsten (W) layer in order from the semiconductor layer 50 side. Note that the titanium layer is provided to reduce contact resistance between the contact plugs 60S and 60D and the low-resistance regions 51S and 51D in the lower layer. Further, the titanium nitride layer is provided as a barrier metal that suppresses diffusion of silicon or the like from the semiconductor layer 50 to the tungsten layer.

The first metals M1 include, for example, the source electrode 30S provided on the contact plug 60S and the drain electrode 30D provided on the contact plug 60D. The first metal M1 may include, for example, aluminum (Al) with a thickness of 500 nm to 1000 nm.

The first low-permittivity region 70 is provided, for example, in at least any region that is between the first metals M1 in a XY in-plane direction of the semiconductor layer 50 and below a lower surface of the first metal M1 in a Z stacking direction of the semiconductor layer 50. Specifically, the first low-permittivity region 70 is provided in a region that is between the source electrode 30S and the drain electrode 30D in the XY in-plane direction of the semiconductor layer 50, and below the lower surface of the first metal M1 and above the gate electrode 20 in the Z stacking direction of the semiconductor layer 50.

Further, the first low-permittivity region 70 may be provided continuously up to a region further above the region described above in the Z stacking direction. Specifically, the first low-permittivity region 70 may be further provided in a region that is between the first metals M1 in the XY in-plane direction of the semiconductor layer 50 and between the lower surface and an upper surface of the first metal M1 in the Z stacking direction. Further, the first low-permittivity region 70 may be further provided in a region that is between the first metals M1 in the XY in-plane direction of the semiconductor layer 50 and above the upper surface of the first metal M1 in the Z stacking direction.

The second low-permittivity region 71 is provided in at least any region that is between each of the contact plugs 60S and 60D and the gate electrode 20 in the XY in-plane direction of the semiconductor layer 50 and below the first low-permittivity region 70 in the Z stacking direction of the semiconductor layer 50. Specifically, the second low-permittivity region 71 is provided on the sides of both side surfaces of the gate electrode 20 in the XY in-plane direction of the semiconductor layer 50. Note that the second low-permittivity region 71 may be provided to be continuous with the first low-permittivity region 70, or may be provided apart from the first low-permittivity region 70.

At least a portion of the second low-permittivity region 71 is provided in a region different from a region provided with the first low-permittivity region 70, when the semiconductor layer 50 is seen in plan view from the stacking direction Z. Specifically, at least a portion of the second low-permittivity region 71 is provided in a region around the periphery of a region provided with the first low-permittivity region 70, in the XY in-plane direction of the semiconductor layer 50. Thus, in the semiconductor device 10, it is possible to configure the first low-permittivity region 70 and the second low-permittivity region 71 in more complicated shapes.

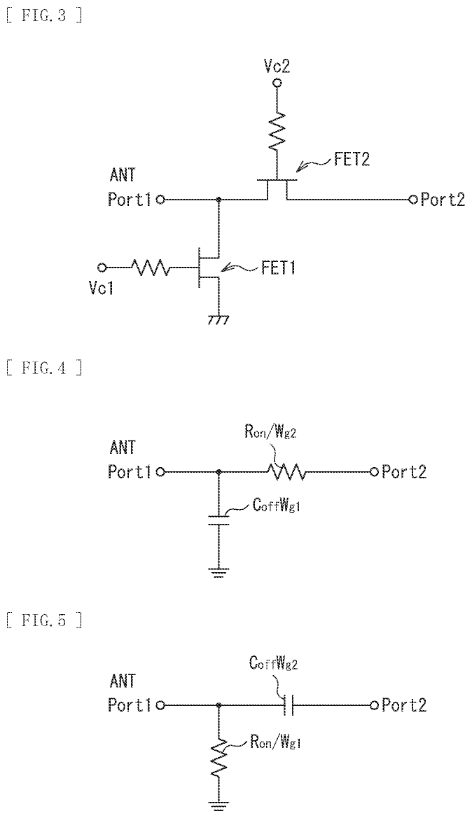

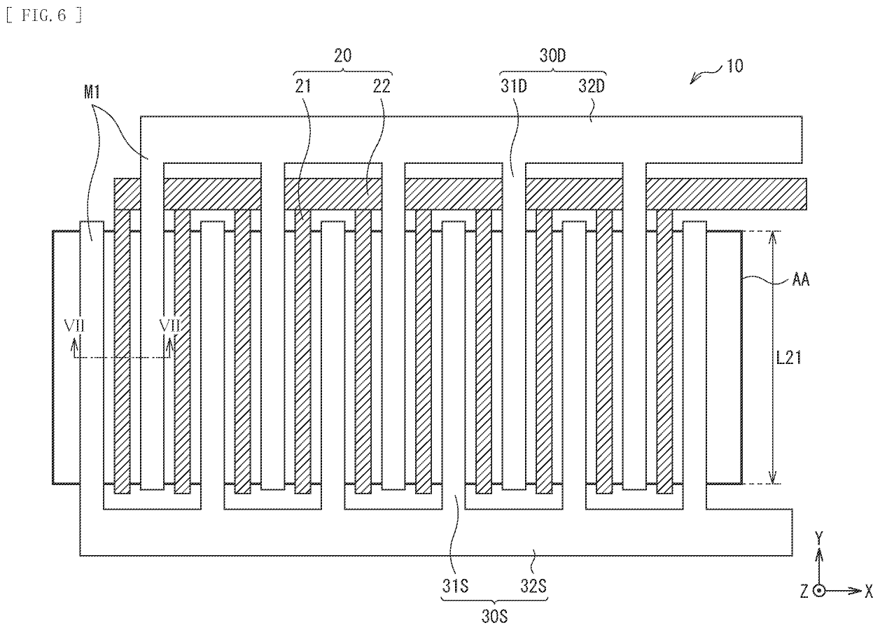

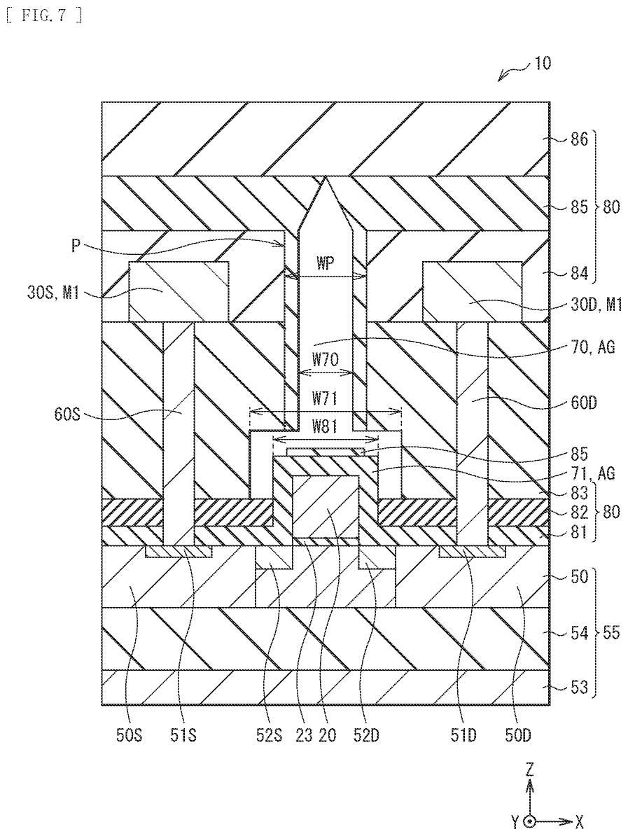

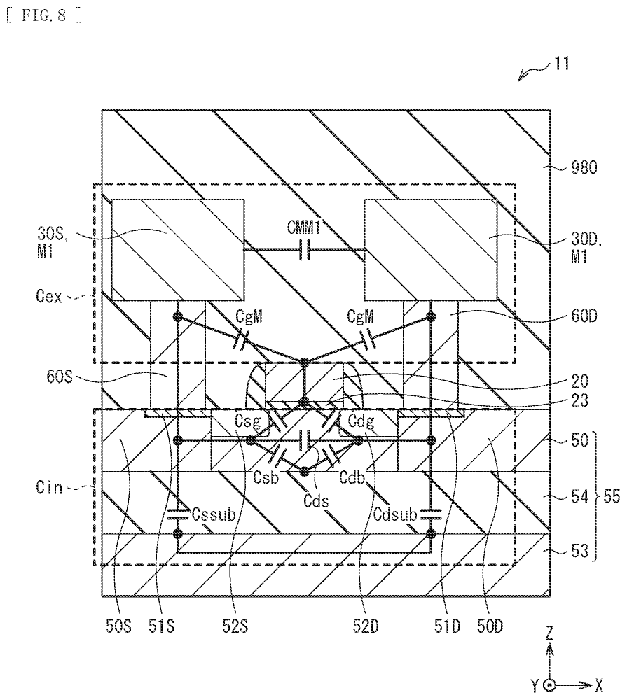

Here, referring to FIG. 8, off-capacitance of a field-effect transistor will be described. FIG. 8 is a schematic longitudinal cross-sectional view of off-capacitance, divided into elements, of a typical field-effect transistor 11. In FIG. 8, components corresponding to the components of the semiconductor device 10 illustrated in FIG. 7 are denoted by the same reference numerals.

As illustrated in FIG. 8, the off-capacitance of the field-effect transistor 11 with a typical structure includes an intrinsic (intrinsic) component Cin generated in the source region 50S and the drain region 50D, the SOI substrate 55, and the like, and an extrinsic (extrinsic) component Cex generated in the gate electrode 20, the contact plugs 60S and 60D, the first metals M1, and the like.

Examples of the intrinsic component CM include capacitances Cssub and Cdsub generated between the source region 50S or the drain region 50D and the support substrate 53, capacitances Csg and Cdg generated between the source region 50S or the drain region 50D and the gate electrode 20, a capacitance Cds generated between the source region 50S and the drain region 50D, capacitances Csb and Cdb generated between the source region 50S or the drain region 50D and a lower portion (body) of the semiconductor layer 50, and the like.

Examples of the extrinsic component Cex include a capacitance CgM between the gate electrode 20 and the contact plugs 60S and 60D or the first metals M1, a capacitance CMM1 generated between the first metals M1, and the like.

To reduce these off-capacitances, it is particularly effective to reduce the extrinsic component Cex. In the semiconductor device 10 according to the present embodiment, the first low-permittivity region 70 and the second low-permittivity region 71 having a lower relative permittivity than the surrounding region are provided in the regions described above. This makes it possible to reduce the extrinsic component Cex of the off-capacitance generated between the gate electrode 20, the contact plugs 60S and 60D, and the first metals M1. Therefore, by reducing the extrinsic component Cex more effectively, the semiconductor device 10 makes it possible to reduce the product of the on-resistance and the off-capacitance (Ron*Coff). Thus, the semiconductor device 10 applied to the radio-frequency switch makes it possible to further reduce loss of the radio-frequency switch.

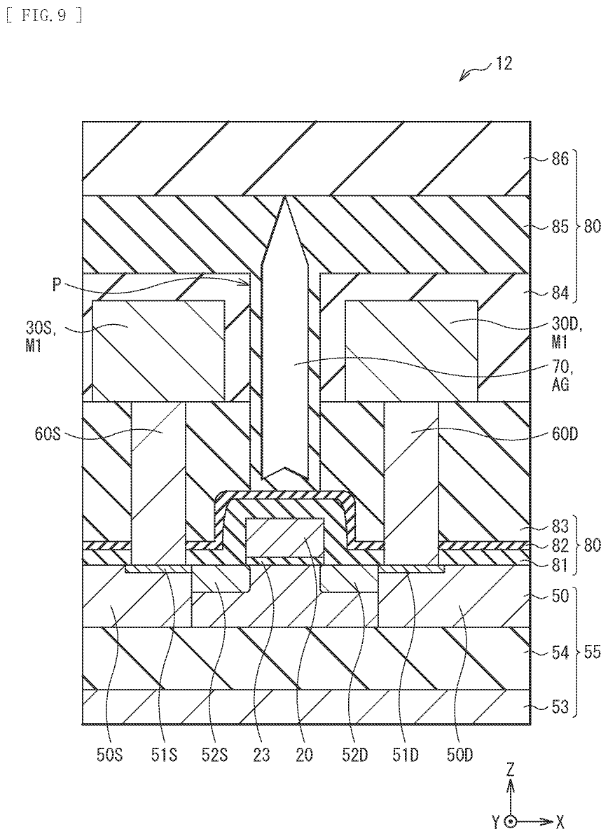

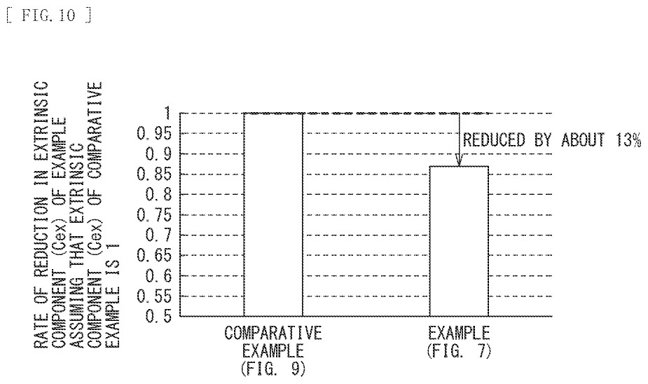

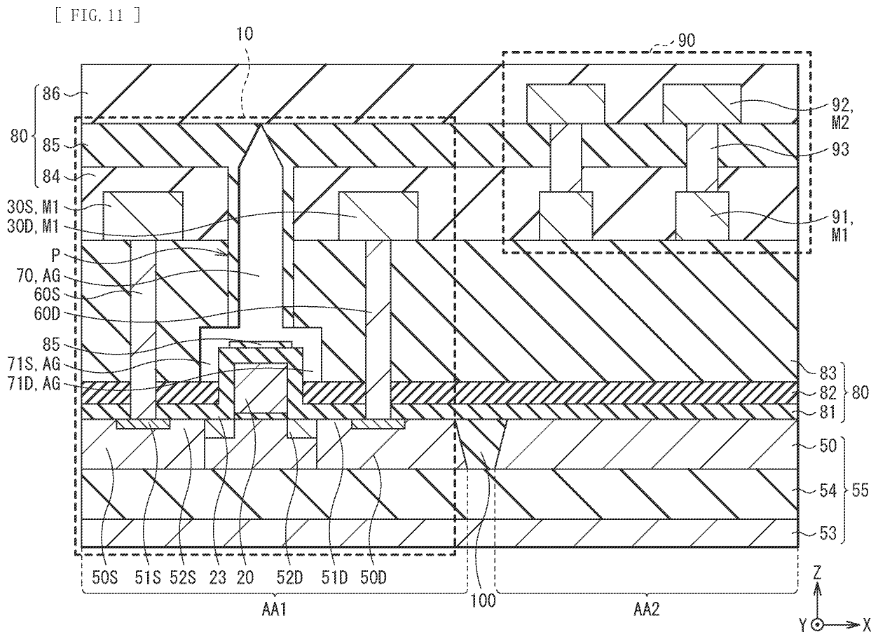

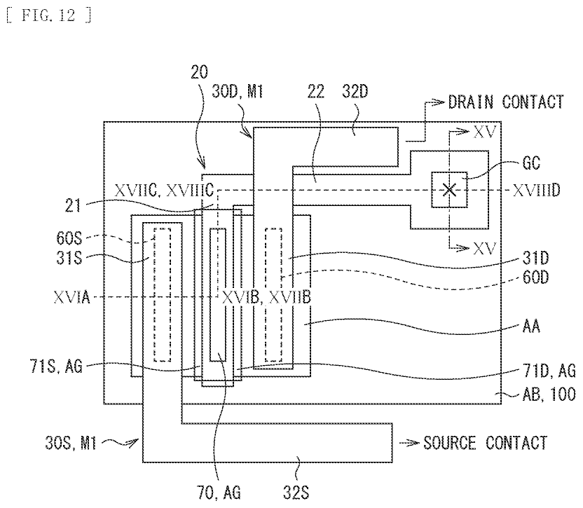

Here, FIG. 10 illustrates results of simulating the magnitude of the extrinsic component Cex of the off-capacitance, for the semiconductor device 10 illustrated in FIG. 7 and a semiconductor device 12 according to a comparative example illustrated in FIG. 9.

FIG. 9 is a longitudinal cross-sectional view of a cross-sectional configuration of the semiconductor device 12 according to the comparative example. As illustrated in FIG. 9, the semiconductor device 12 according to the comparative example differs from the semiconductor device 10 according to the present embodiment in that no second low-permittivity region is provided between each of the contact plugs 60S and 60D and the gate electrode 20 in the XY in-plane direction of the semiconductor layer 50 and below the first low-permittivity region 70 in the Z stacking direction of the semiconductor layer 50. That is, the semiconductor device 12 according to the comparative example differs from the semiconductor device 10 according to the present embodiment in that, although the similar first low-permittivity region 70 is provided, the second low-permittivity region 71 is not provided on both sides of the gate electrode 20 in the XY in-plane direction of the semiconductor layer 50.

FIG. 10 illustrates a simulation result of the extrinsic component Cex in the semiconductor device 10 according to the present embodiment as an example, and illustrates a simulation result of the extrinsic component Cex in the semiconductor device 12 according to the comparative example as a comparative example. As illustrated in FIG. 10, the results indicate that the magnitude of the extrinsic component Cex in the example is reduced with respect to the magnitude of the extrinsic component Cex in the comparative example. Therefore, the results indicate that the semiconductor device 10 according to the present embodiment makes it possible to further reduce the off-capacitance by further providing the second low-permittivity region 71.

Here, returning to FIG. 7, the description of the configuration of the semiconductor device 10 according to the present embodiment will be restarted.

The semiconductor device 10 illustrated in FIG. 7 further includes at least one or more insulating films 80 provided on the semiconductor layer 50 to cover the gate electrode 20, and an opening P provided toward an upper surface of the gate electrode 20 from an upper surface of the at least one or more insulating films 80.

The opening P is provided in a planar region corresponding to the gate electrode 20 in a case where the at least one or more insulating films 80 are seen in plan view from the stacking direction Z. Because the opening P is provided between the source electrode 30S and the drain electrode 30D, an opening width WP of the opening P is about 100 nm to about 1000 nm, for example.

The first low-permittivity region 70 is preferably provided inside such an opening P. Further, it is preferable that the second low-permittivity region 71 be provided to be spatially continuous with the opening P, and be provided to be spatially continuous with the first low-permittivity region 70 provided inside the opening P. In either the X direction or the Y direction, the first low-permittivity region 70 and the second low-permittivity region 71 may be provided so that the centers of the regions match each other, or may be provided in regions independent of each other.

The at least one or more insulating films 80 preferably include a plurality of insulating films including materials having different etching rates. Thus, by using the difference in the etching rate between the insulating films, the at least one or more insulating films 80 make it possible to control an etching-stop position of the opening P with high accuracy in manufacturing steps to be described later.

Specifically, the at least one or more insulating films 80 may include a first insulating film 81, a second insulating film 82, and a third insulating film 83.

The first insulating film 81 is provided to cover a surface of the gate electrode 20 (i.e., the upper surface and the side surface of the gate electrode 20) and an upper surface of the semiconductor layer 50.

The second insulating film 82 is provided to cover a surface of the first insulating film 81. Note that the second insulating film 82 is not provided on the surface of the first insulating film 81 provided on the surface of the gate electrode 20 (i.e., the upper surface and the side surface of the gate electrode 20), and exposes the first insulating film 81 to the second low-permittivity region 71. This is because, in the semiconductor device 10, the second low-permittivity region 71 is formed between the first insulating film 81 and the third insulating film 83 by removing the second insulating film 82, as will be described in the manufacturing steps to be described later.

The third insulating film 83 is provided between a surface of the second insulating film 82 and the lower surface of the first metal M1. The third insulating film 83 is provided to bury the gate electrode 20, and forms the second low-permittivity region 71 between the first insulating film 81 and the third insulating film 83.

Here, the second insulating film 82 preferably includes a material having a different etching rate from a material included in the first insulating film 81 and the third insulating film 83. For example, it is preferable that the second insulating film 82 include a silicon nitride (SiN) film, and the first insulating film 81 and the third insulating film 83 include a silicon oxide (SiOₓ) film having a different etching rate from the silicon nitride (SiN). Thus, in the semiconductor device 10, causing the second insulating film 82 to function as an etching stopper layer makes it possible to easily form the opening P penetrating the third insulating film 83 to reach an upper surface of the second insulating film 82. Further, selectively removing the second insulating film 82 by performing isotropic etching via the opening P makes it possible to easily form the second low-permittivity region 71 below the opening P.

Further, the at least one or more insulating films 80 may further include a fourth insulating film 84. Specifically, the fourth insulating film 84 may be provided to cover an upper surface of the third insulating film 83 and a surface of the first metal M1 (i.e., the upper surface and a side surface of the first metal M1). In such a case, the opening P is provided from an upper surface of the fourth insulating film 84 to penetrate the fourth insulating film 84 and the third insulating film 83. The fourth insulating film 84 may include a silicon oxide (SiOₓ) film, for example.

Further, the at least one or more insulating films 80 may further include a fifth insulating film 85. Specifically, the fifth insulating film 85 may be provided on the fourth insulating film 84 and may block an upper portion of the opening P. The fifth insulating film 85 may include a silicon oxide (SiOₓ) film, for example.

Further, a sixth insulating film 86 including a silicon oxide (SiOₓ) film, for example, may be provided in an upper layer of the fifth insulating film 85, as necessary.

In the semiconductor device 10 according to the present embodiment, an air gap AG (Air Gap) may be provided as the first low-permittivity region 70 in at least a portion of the inside of the opening P. For example, the air gap AG of the first low-permittivity region 70 may be provided to be spatially continuous with the second low-permittivity region 71 similarly formed as an air gap AG below the first low-permittivity region 70.

The first low-permittivity region 70 and the second low-permittivity region 71 are not particularly limited in configuration inside the region, as long as the regions have a lower relative permittivity than the silicon oxide (SiOₓ: relative permittivity 3.9) film included in the third insulating film 83 and the fourth insulating film 84. For example, the first low-permittivity region 70 and the second low-permittivity region 71 may be configured so that the inside of the air gap AG includes air (relative permittivity 1.0), or may be configured so that the inside of the air gap AG is a vacuum. Further, the first low-permittivity region 70 and the second low-permittivity region 71 may be configured by filling a portion or the whole of the inside of the air gap AG with a low-permittivity material. Note that the low-permittivity material refers to, for example, a dielectric material with relative permittivity of 3 or less.

In a case where the first low-permittivity region 70 and the second low-permittivity region 71 include the air gap AG, the air gap AG is hermetically sealed by the fifth insulating film 85 by an upper portion of the air gap AG being blocked by the fifth insulating film 85. Note that, when blocking the air gap AG, a portion of the fifth insulating film 85 may enter the inside of the air gap AG. In such a case, the fifth insulating film 85 covers a portion of a side surface or a bottom surface of the opening P.

In the XY in-plane direction, widths with which the first low-permittivity region 70 and the second low-permittivity region 71 are formed are not particularly limited. Note that the width with which the first low-permittivity region 70 is formed may be, for example, smaller than a width of the first insulating film 81 provided on the surface of the gate electrode 20, in one cross-section taken in the stacking direction Z. Specifically, a width W70 of the first low-permittivity region 70 may be smaller than a width W81 of the first insulating film 81 covering the upper surface and the side surface of the gate electrode 20.

In a case where the second insulating film 82 is formed on the surface of the first insulating film 81 on the upper surface and the side surface of the gate electrode 20, the width W70 of the first low-permittivity region 70 may be smaller than widths of the first insulating film 81 and the second insulating film 82 covering the upper surface and the side surface of the gate electrode 20. Further, in a case where the first insulating film 81 is not formed on the upper surface and the side surface of the gate electrode 20, the width W70 of the first low-permittivity region 70 may be smaller than a width of the gate electrode 20.

Further, the width with which the second low-permittivity region 71 is formed may be larger than the width of the first insulating film 81 provided on the surface of the gate electrode 20, in one cross-section taken in the stacking direction Z. Specifically, a width W71 of the second low-permittivity region 71 may be larger than the width W81 of the first insulating film 81 covering the upper surface and the side surface of the gate electrode 20 and smaller than a width between the contact plugs 60S and 60D.

In a case where the second insulating film 82 is formed on the surface of the first insulating film 81 on the upper surface and the side surface of the gate electrode 20, the width W71 of the second low-permittivity region 71 may be larger than the widths of the first insulating film 81 and the second insulating film 82 covering the upper surface and the side surface of the gate electrode 20. Further, in a case where the first insulating film 81 is not formed on the upper surface and the side surface of the gate electrode 20, the width W71 of the second low-permittivity region 71 may be larger than the width of the gate electrode 20.

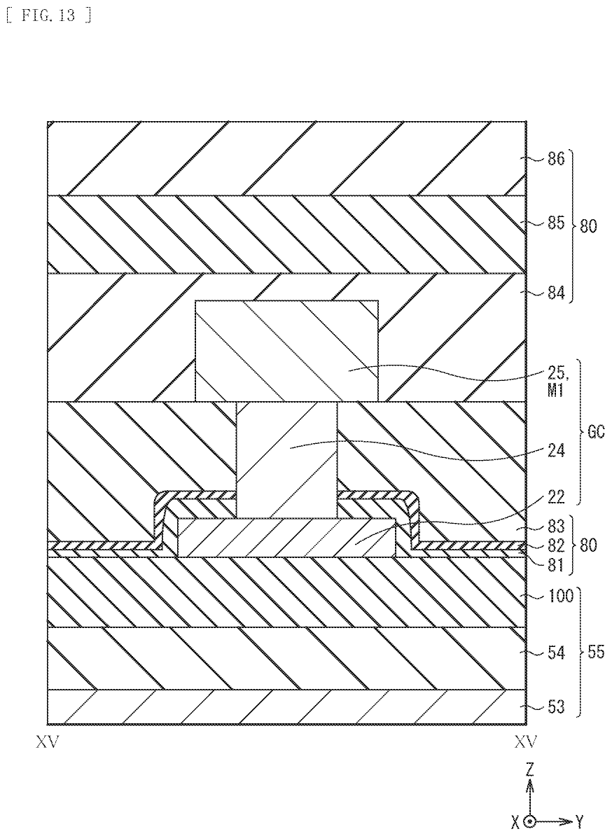

Furthermore, referring to FIGS. 11 and 12, description will be given on the positional relationship between the first low-permittivity region 70 and the second low-permittivity region 71 and a multilayer wiring part 90 in the semiconductor device 10 according to the present embodiment. The multilayer wiring part 90 is provided with wiring lines that transmit signals taken out from the electrodes of the semiconductor device 10.

FIG. 11 is a schematic diagram illustrating the positional relationship, in the Z stacking direction, between the first low-permittivity region 70 and the second low-permittivity region 71 and the multilayer wiring part 90 in the semiconductor device 10 illustrated in FIG. 7.

As illustrated in FIG. 11, the multilayer wiring part 90 includes a first wiring layer 91 and a second wiring layer 92, for example. The first wiring layer 91 is provided, for example, in the same layer as the first metals M1 including the source electrode 30S and the drain electrode 30D. The second wiring layer 92 is provided above the first wiring layer 91, and is coupled to the first wiring layer 91 via a contact plug 93, for example.

The first low-permittivity region 70 and the second low-permittivity region 71 in the semiconductor device 10 are provided inside a device region AA1 of the active region AA activated by introducing the conductivity-type impurity into the semiconductor layer 50. On the other hand, the multilayer wiring part 90 is provided inside a wiring region AA2 that is inside the active region AA and outside the device region AA1. The device region AA1 and the wiring region AA2 are isolated from each other by, for example, a device isolation layer 100 formed by a STI (Shallow Trench Isolation) method.

Note that the first low-permittivity region 70 and the second low-permittivity region 71 may not be provided between wiring lines of the first wiring layer 91 and between wiring lines of the second wiring layer 92 of the multilayer wiring part 90. That is, the first low-permittivity region 70 and the second low-permittivity region 71 are at least provided in the semiconductor device 10 in the device region AA1 of the active region AA.

FIG. 12 is a schematic diagram illustrating the positional relationship, in the XY in-plane direction, between the first low-permittivity region 70 and the second low-permittivity region 71 and the multilayer wiring part 90 in the semiconductor device 10 illustrated in FIG. 7.

As illustrated in FIG. 12, the semiconductor device 10, the first low-permittivity region 70, and the second low-permittivity region 71 are provided inside the active region AA. On the other hand, in a device isolation region AB outside the active region AA, the device isolation layer 100 formed by the STI method is provided over the entire surface, instead of the semiconductor layer 50, and a gate contact GC is provided.

More specifically, the active region AA is provided with the finger part 21 of the gate electrode 20, the finger part 31S of the source electrode 30S, and the finger part 31D of the drain electrode 30D.

The finger part 21 of the gate electrode 20 is provided to extend in one direction (e.g., the Y direction). The finger part 31S of the source electrode 30S and the finger part 31D of the drain electrode 30D are provided on both sides of the finger part 21 of the gate electrode 20 to extend in a direction parallel to the extending direction of the finger part 21 of the gate electrode 20.

The contact plugs 60S and 60D are provided below the finger part 31S of the source electrode 30S and the finger part 31D of the drain electrode 30D to extend in a direction parallel to the extending direction of the finger part 21 of the gate electrode 20.

The first low-permittivity region 70 is provided above the finger part 21 of the gate electrode 20 to extend in a direction parallel to the extending direction of the finger part 21 of the gate electrode 20. Further, the second low-permittivity region 71 is provided on the side of the finger part 21 of the gate electrode 20 to extend in a direction parallel to the extending direction of the finger part 21 of the gate electrode 20. That is, when the semiconductor layer 50 is seen in plan view from the Z stacking direction, the first low-permittivity region 70 is provided in a region overlapping the finger part 21 of the gate electrode 20 in the XY in-plane direction, and the second low-permittivity region 71 is provided in regions on both sides of the finger part 21 of the gate electrode 20 in the XY in-plane direction.

The device isolation region AB is provided with the linking part 22 of the gate electrode 20, the linking part 32S of the source electrode 30S, and the linking part 32D of the drain electrode 30D.

The linking part 22 of the gate electrode 20 is coupled to the gate contact GC. Further, the linking part 32S of the source electrode 30S is coupled to the unillustrated source contact, and the linking part 32D of the drain electrode 30D is coupled to the unillustrated drain contact.

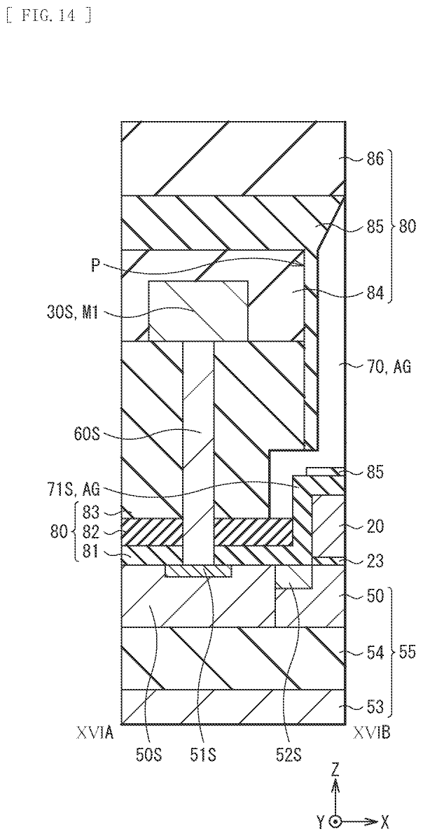

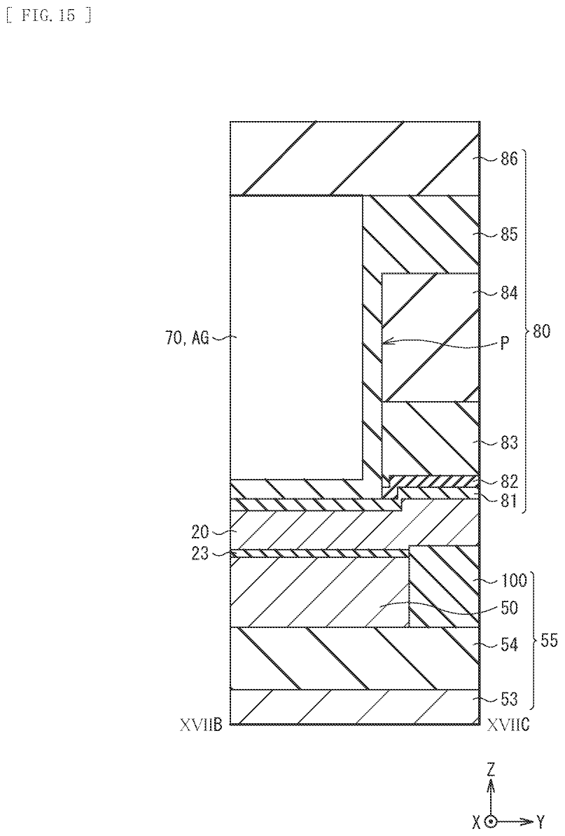

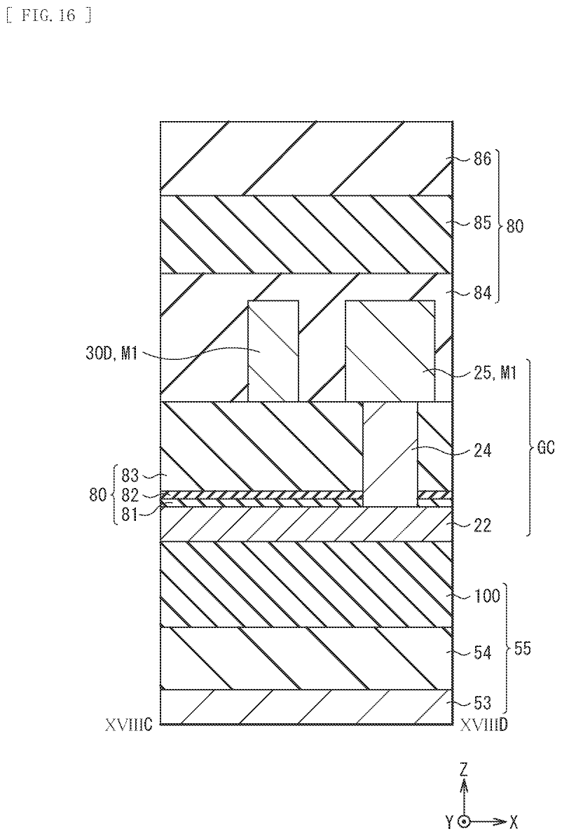

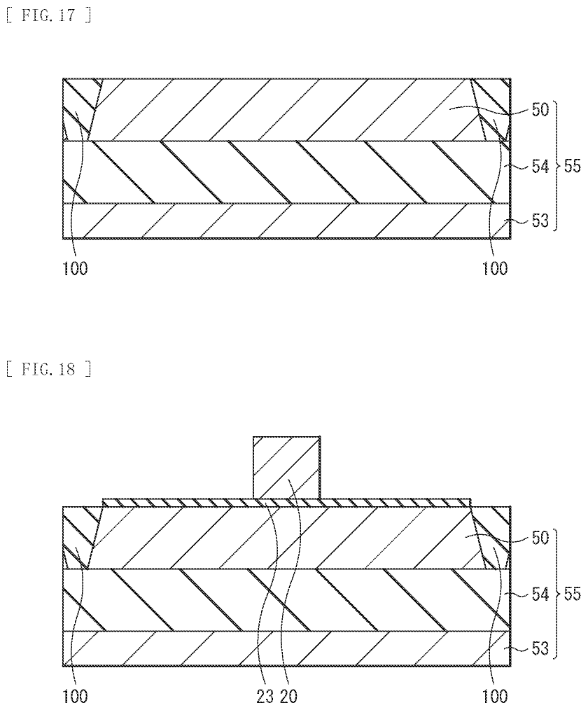

Here, referring to FIGS. 13 to 16, cross-sectional configurations, in the Z stacking direction, of the configurations illustrated in FIG. 12 will be described. FIG. 13 is a longitudinal cross-sectional view of the cross-sectional configuration along line XV-XV in FIG. 12. FIG. 14 is a longitudinal cross-sectional view of the cross-sectional configuration along line XVIA-XVIB in FIG. 12. FIG. 15 is a longitudinal cross-sectional view of the cross-sectional configuration along line XVIIB-XVIIC in FIG. 12. FIG. 16 is a longitudinal cross-sectional view of the cross-sectional configuration along line XVIIIC-XVIIID in FIG. 12.

As illustrated in FIG. 12, the gate contact GC may be configured by providing the linking part 22 of the gate electrode 20, a gate contact plug 24, and a gate contact layer 25 in order on the device isolation layer 100 formed by the STI method. The gate contact plug 24 has a configuration similar to those of the contact plugs 60S and 60D, and is provided in the same layer as the contact plugs 60S and 60D. The gate contact layer 25 has a configuration similar to those of the source electrode 30S and the drain electrode 30D, and is provided in the same layer as the first metals M1 including the source electrode 30S and the drain electrode 30D.

As illustrated in FIGS. 12 to 16, the first low-permittivity region 70 is preferably provided to avoid the gate contact GC. One reason for this is that it is difficult to provide the gate contact plug 24 on the linking part 22 in a case where the first low-permittivity region 70 is provided on the linking part 22 of the gate contact GC. Further, in a case where the first low-permittivity region 70 is not provided on the linking part 22 of the gate contact GC, similarly, the second low-permittivity region 71 is not provided. Further, as with the gate electrode 20, the gate contact GC is preferably covered by the at least one or more insulating films 80 (i.e., the first insulating film 81 to the sixth insulating film 86). This allows for protection of the gate contact GC by the at least one or more insulating films 80, without exposing the gate contact GC, which makes it possible to maintain reliability of the gate contact GC.

(1.3. Method of Manufacturing Semiconductor Device)

Now, referring to FIGS. 17 to 29, a method of manufacturing the semiconductor device 10 according to the present embodiment will be described. FIGS. 17 to 29 are longitudinal cross-sectional views of the respective steps of manufacturing the semiconductor device 10.

First, as illustrated in FIG. 17, the SOI substrate 55 in which the buried oxide film 54 and the semiconductor layer 50 are stacked on the support substrate 53 is prepared. Next, the device region AA1 is defined in the active region AA, by forming the device isolation layer 100 in the semiconductor layer 50 of the SOI substrate 55 by the STI method.

Next, as illustrated in FIG. 18, the gate electrode 20 is formed on the semiconductor layer 50 via the gate insulating film 23.

Specifically, for example, after forming an implantation-through film including a silicon oxide film by a thermal oxidation method, well implantation and channel implantation of a second conductivity-type impurity (e.g., a p-type impurity, such as boron (B) or aluminum (Al)) are performed on the active region AA, and thereafter the implantation-through film is removed. Thereafter, the gate insulating film 23 including silicon oxide, for example, is formed with a thickness of about 5 nm to about 15 nm by the thermal oxidation method.

Subsequently, by a CVD (Chemical Vapor Deposition) method, a gate electrode material film (unillustrated) including polysilicon is formed with a thickness of about 100 nm to about 200 nm on the semiconductor layer 50 and the gate insulating film 23. Next, the formed gate electrode material film is processed by photolithography and etching to form the gate electrode 20 on the upper surface of the semiconductor layer 50.

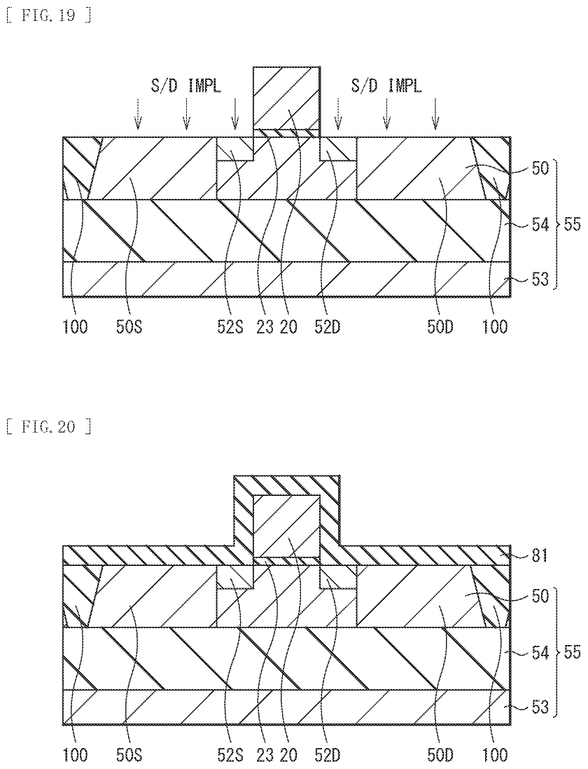

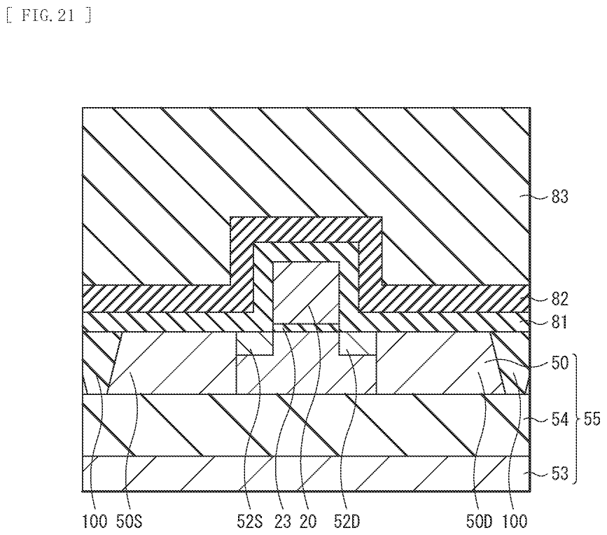

Subsequently, as illustrated in FIG. 19, implantation S/D IMPL of the first conductivity-type impurity (e.g., an n-type impurity, such as arsenic (As) or phosphorus (P)) is performed, by using the gate electrode 20 and unillustrated offset spacers as a mask. Thus, the extension regions 52S and 52D are formed in the semiconductor layer 50 on both sides of the gate electrode 20. Next, unillustrated sidewalls are formed on the both side surfaces of the gate electrode 20, and the implantation S/D IMPL of the first conductivity-type impurity is performed again. This makes it possible to form the source region 50S and the drain region 50D in the semiconductor layer 50 on both sides across the gate electrode 20. Note that the sidewall is removed after the formation of the source region 50S and the drain region 50D.

Next, as illustrated in FIG. 20, the first insulating film 81 including silicon oxide is formed with a thickness of about 10 nm to about 100 nm on the surface of the gate electrode 20 and the upper surface of the semiconductor layer 50, by the CVD method, for example.

Subsequently, as illustrated in FIG. 21, the second insulating film 82 including silicon nitride having a different etching rate from the silicon oxide forming the first insulating film 81 is formed with a thickness of about 10 nm to about 100 nm on the surface of the first insulating film 81, by the CVD method, for example. Thereafter, the third insulating film 83 including silicon oxide is formed with a thickness of about 500 nm to about 1500 nm on the second insulating film 82, by the CVD method, for example.

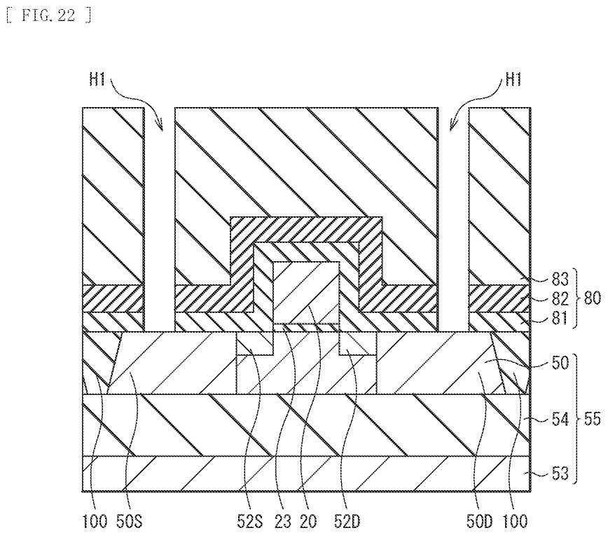

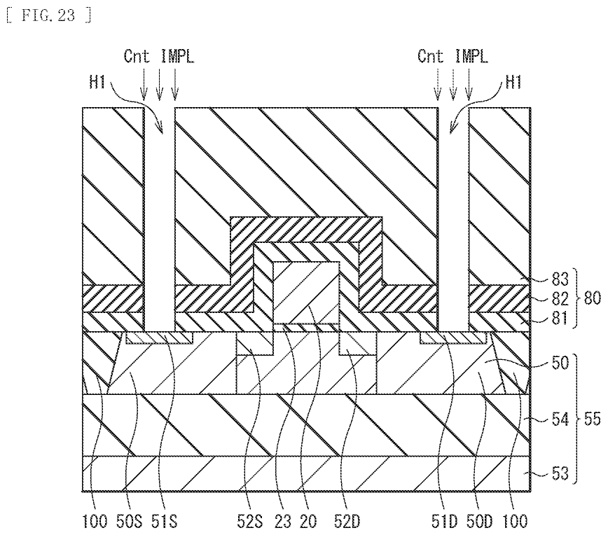

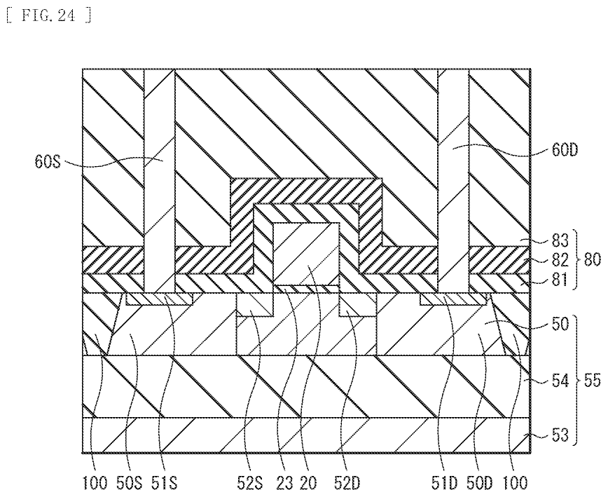

Next, as illustrated in FIG. 22, the third insulating film 83, the second insulating film 82, and the first insulating film 81 at positions corresponding to the source region 50S and the drain region 50D are removed by photolithography and etching. Thus, contact holes H1 exposing the source region 50S and the drain region 50D are formed. As illustrated in FIG. 12, the contact holes H1 are provided to extend in a direction parallel to the extending direction of the finger part 21 of the gate electrode 20.

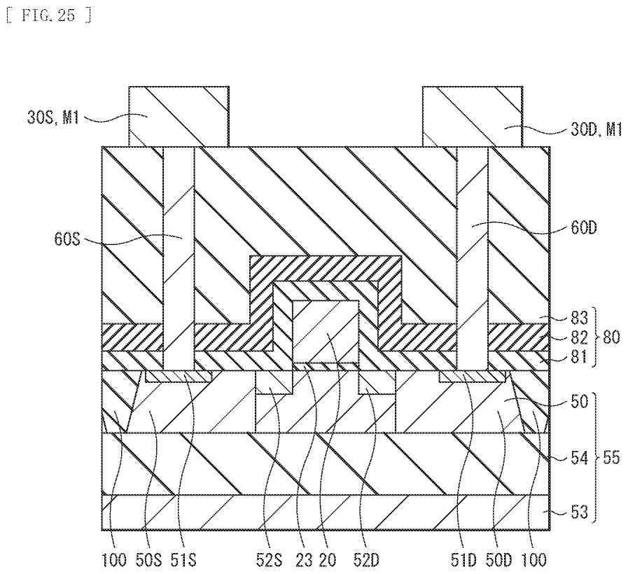

Subsequently, as illustrated in FIG. 23, implantation Cnt IMPL of the first conductivity-type impurity (e.g., an n-type impurity, such as arsenic (As) or phosphorus (P)) with high concentration is performed on the source region 50S and the drain region 50D via the contact holes HE Thus, the low-resistance regions MS and MD are formed in the semiconductor layer 50.

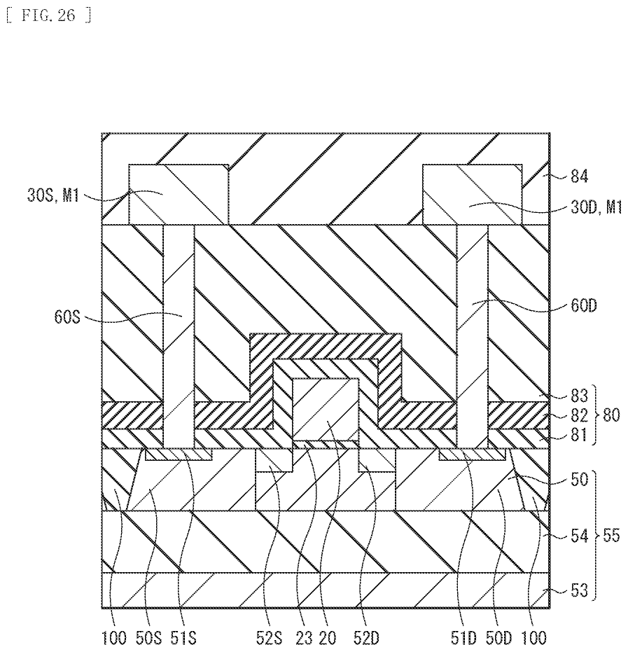

Next, as illustrated in FIG. 24, the titanium layer, the titanium nitride layer, and the tungsten layer are stacked in order in the contact holes H1 to form the contact plugs 60S and 60D having a stacked structure. This allows the contact plugs 60S and 60D to be electrically coupled to the source region 50S and the drain region 50D via the low-resistance regions 51S and 51D. As illustrated in FIG. 12, the contact plugs 60S and 60D are provided to extend in a direction parallel to the extending direction of the finger part 21 of the gate electrode 20.

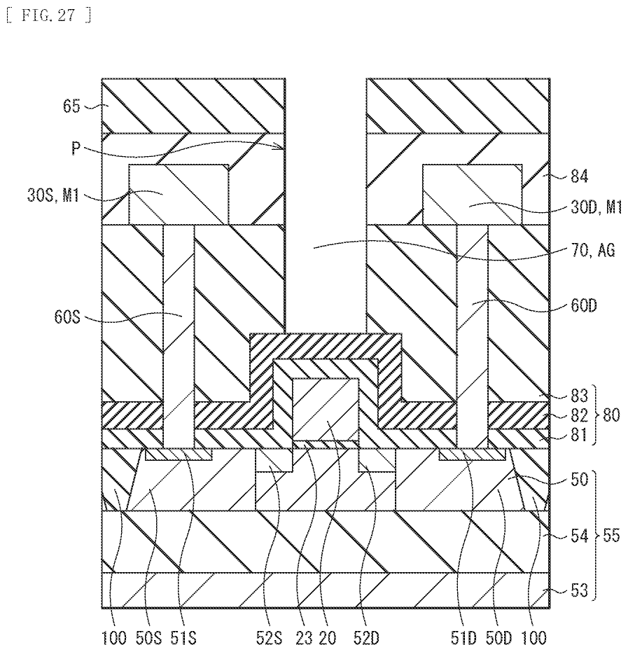

Thereafter, as illustrated in FIG. 25, the source electrode 30S and the drain electrode 30D including aluminum (Al) are formed, as the first metals M1, on the contact plugs 60S and 60D. As illustrated in FIG. 12, the finger part 31S of the source electrode 30S and the finger part 31D of the drain electrode 30D are provided to extend in a direction parallel to the extending direction of the finger part 21 of the gate electrode 20.

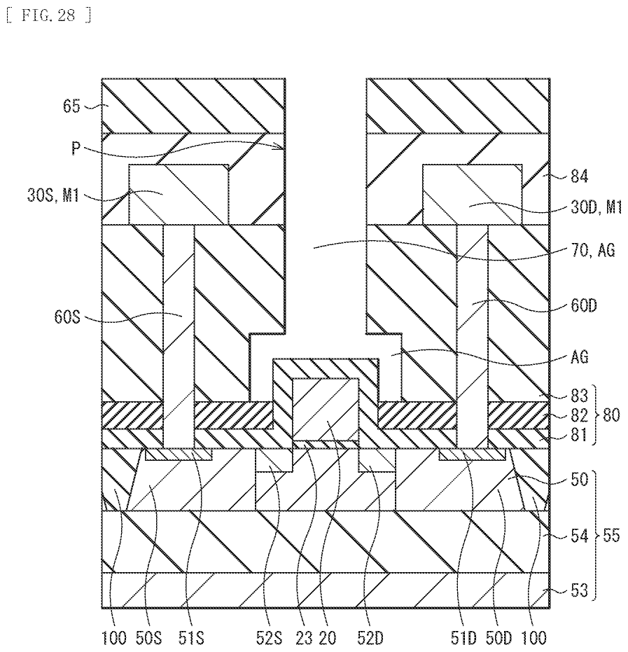

Subsequently, as illustrated in FIG. 26, the fourth insulating film 84 including silicon oxide is formed on the upper surface of the third insulating film and the surface of the first metal M1 by the CVD method, for example.

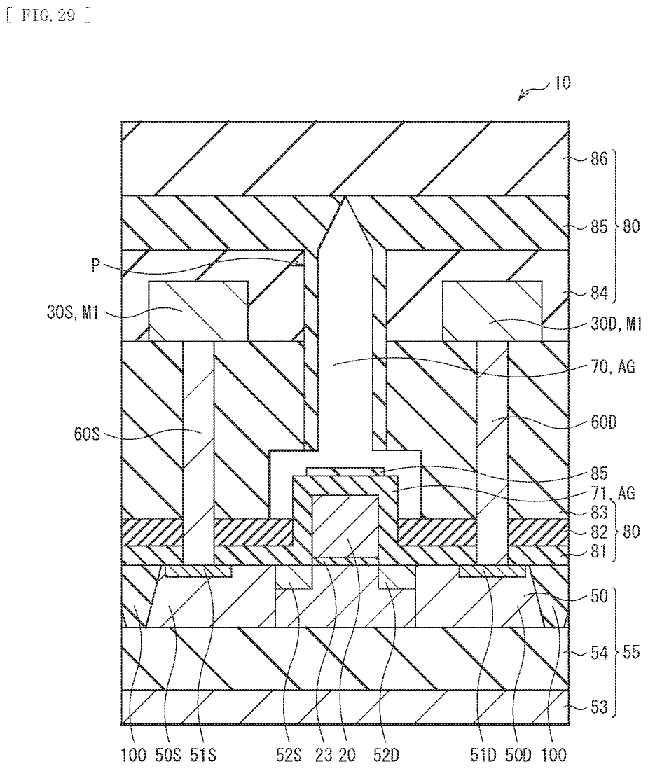

Next, as illustrated in FIG. 27, the opening P penetrating the fourth insulating film 84 and the third insulating film 83 and exposing the second insulating film 82 is formed.

Specifically, first, a low-permittivity-region-forming resist 65 is patterned by photolithography. Thereafter, the opening P is formed by removing a portion of the fourth insulating film 84 and the third insulating film 83 by dry etching using the patterned low-permittivity-region-forming resist 65 as a mask. Note that the etching in forming the opening P is performed by highly anisotropic dry etching. Using such highly anisotropic etching makes it possible to form the opening P with a high aspect ratio in a desired region with high accuracy.

Here, the opening P is provided in a region between the first metals M1 in the XY in-plane direction of the semiconductor layer 50. Specifically, the opening P is provided in a region between the source electrode 30S and the drain electrode 30D (i.e., above the gate electrode 20). The opening width WP of the opening P is about 100 nm to about 1000 nm, for example. In the formation of the opening P, the etching of the opening P proceeds to the fourth insulating film 84 and the third insulating film 83 including silicon oxide, stopping at the upper surface of the second insulating film 82, because the second insulating film 82 functions as an etching stopper. The air gap AG inside the opening P formed in this step serves as the first low-permittivity region 70.

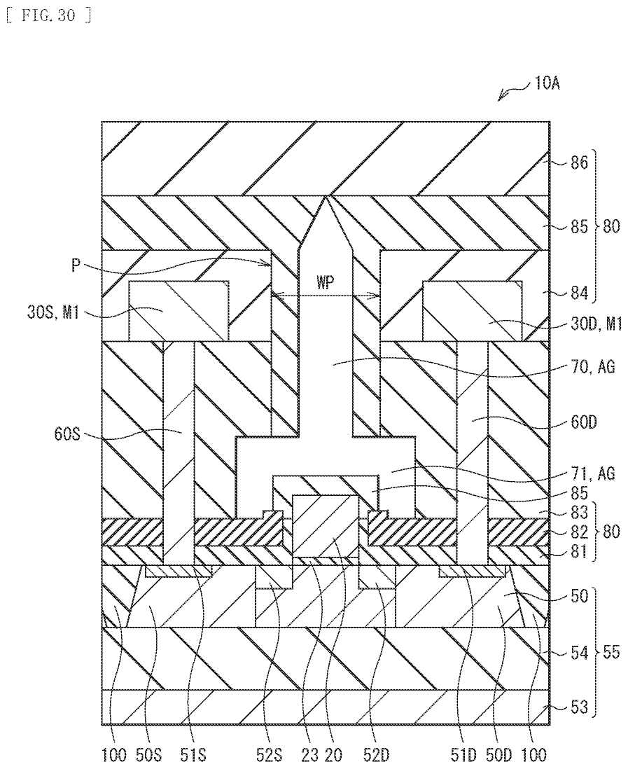

Subsequently, as illustrated in FIG. 28, a portion of the second insulating film 82 is etched via the opening P, with the low-permittivity-region-forming resist 65 left. Thus, the air gap AG continuous with the air gap AG provided between the first metals M1 is formed on the side of the gate electrode 20. Note that the etching in removing a portion of the second insulating film 82 is performed by isotropic dry etching, wet etching, or the like. Using such isotropic etching makes it possible to efficiently etch the second insulating film 82 provided on the upper surface and the side surface of the gate electrode 20, and to form the air gap AG in a wider region.

In this step, the air gap AG formed by removing the second insulating film 82 serves as the second low-permittivity region 71. That is, the air gap AG serving as the first low-permittivity region 70 is formed above the gate electrode 20, and the air gap AG serving as the second low-permittivity region 71 is formed on the side of the gate electrode 20. Thus, the semiconductor device 10 makes it possible to further reduce the extrinsic component of the off-capacitance.

Next, as illustrated in FIG. 29, after peeling off the low-permittivity-region-forming resist 65, the fifth insulating film 85 including silicon oxide is formed on the fourth insulating film 84 by, for example, the CVD method under a condition where the ability to fill the inside of the air gap AG is low. In the CVD method under such a condition, the fifth insulating film 85 is deposited while overhanging on the upper portion of the opening P. Thus, the upper portion of the opening P is blocked by the fifth insulating film 85, before the inside of the opening P is filled with the fifth insulating film 85. Thus, the air gap AG hermetically sealed is formed inside the opening P. At this time, the side surface of the opening P, and the upper surface of the first insulating film 81 covering the gate electrode 20 may be covered with the fifth insulating film 85 that enters the inside of the opening P.

The air gaps AG function as the first low-permittivity region 70 and the second low-permittivity region 71, because they have a lower relative permittivity than the silicon oxide (relative permittivity 3.9) forming the third insulating film 83, the fourth insulating film 84, and the fifth insulating film 85. The inside of the air gap AG may be a vacuum, or there may be air (relative permittivity 1.0). Alternatively, the inside of the air gap AG may be filled with a material with a lower relative permittivity than the silicon oxide (relative permittivity 3.9) forming the third insulating film 83, the fourth insulating film 84, and the fifth insulating film 85.

Through the above steps, the air gaps AG are provided in regions corresponding to the first low-permittivity region 70 including at least any region that is between the first metals M1 in the XY in-plane direction and below the lower surface of the first metal M1 in the Z stacking method, and the second low-permittivity region 71 including at least any region between the contact plugs 60S and 60D and the gate electrode 20 in the XY in-plane direction and below the first low-permittivity region 70 in the Z stacking method. At this time, the air gap AG of the first low-permittivity region 70 and the air gap AG of the second low-permittivity region 71 are formed to be spatially continuous with each other.

Thereafter, the sixth insulating film 86 is formed on the fifth insulating film 85, as necessary. Thus, the semiconductor device 10 illustrated in FIG. 7 is formed. Note that, although not illustrated, it is also possible to form second metals M2, and further third metals M3, by sequentially forming a metal layer and an insulating film, as with the first metals M1 and the fourth insulating film 84, on the fifth insulating film 85.

As described above, in the semiconductor device 10, the first low-permittivity region 70 and the second low-permittivity region 71 are provided in the regions described above. This makes it possible to reduce the capacitance CgM between the gate electrode 20 and the contact plugs 60S and 60D and the first metals M1, and the capacitance CMM1 generated between the first metals M1. Therefore, the semiconductor device 10 is able to reduce the extrinsic component Cex of the off-capacitance. Thus, the semiconductor device 10 makes it possible to reduce the product of the on-resistance and the off-capacitance (Ron*Coff). This helps to promote a reduction in loss, which is an important characteristic of a radio-frequency switch.

Further, in the semiconductor device 10, the first low-permittivity region 70 may be provided to further extend to a region between the lower surface and the upper surface of the first metal M1 and a region above the upper surface of the first metal M1 in the Z stacking direction. In such a case, the semiconductor device 10 makes it possible to further reduce the capacitance CgM between the gate electrode 20 and the contact plugs 60S and 60D and the first metals M1, and the capacitance CMM1 generated between the first metals M1.

Furthermore, the semiconductor device 10 is preferably configured by providing, on the semiconductor layer 50, the at least one or more insulating films 80 including insulating films including materials having different etching rates. Thus, in the semiconductor device 10, using the difference in the etching rate between the insulating films makes it possible to control, with high accuracy, the etching-stop position of the opening P used to form the first low-permittivity region 70 and the second low-permittivity region 71. Therefore, according to the present embodiment, it is possible to manufacture the semiconductor device 10 more stably and with higher reliability.

Note that the filling state of the opening P with the fifth insulating film 85 and the covering state of the side surface of the opening P and the upper surface of the first insulating film 81 covering the gate electrode 20, illustrated in the longitudinal cross-sectional view of FIG. 7 etc., are merely examples, and do not limit the structure of the semiconductor device 10 according to the present embodiment.

### 2. Second Embodiment

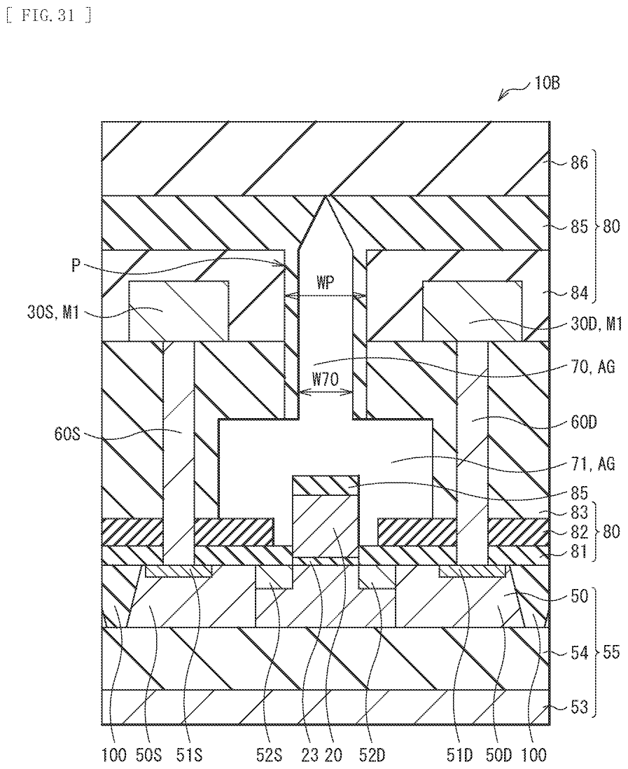

Next, referring to FIG. 30, a configuration of a semiconductor device according to a second embodiment of the present disclosure will be described. FIG. 30 is a longitudinal cross-sectional view of a cross-sectional configuration of a semiconductor device 10A according to the present embodiment. As with FIG. 7, FIG. 30 illustrates the cross-sectional configuration along line VII-VII in FIG. 6.

As illustrated in FIG. 30, the semiconductor device 10A according to the present embodiment differs from the semiconductor device 10 illustrated in FIG. 7 in that the air gaps AG serving as the first low-permittivity region 70 and the second low-permittivity region 71 are expanded by expanding a range of the isotropic etching of the second insulating film 82 performed via the opening P.

Specifically, in the semiconductor device 10A, the air gap AG may be formed in a wider range by removing, in addition to the second insulating film 82, the first insulating film 81 covering the upper surface of the gate electrode 20, and further the third insulating film 83 and the fourth insulating film 84 on the side surface of the opening P. Thus, the semiconductor device 10A makes it possible to further reduce the extrinsic component Cex of the off-capacitance, including the capacitance CgM between the gate electrode 20 and the contact plugs 60S and 60D or the first metals M1, the capacitance CMM1 generated between the first metals M1, and the like.

In the semiconductor device 10A according to the present embodiment, because the opening width WP of the opening P is expanded, the fifth insulating film 85 with a film thickness thicker than in the semiconductor device 10 illustrated in FIG. 7 may be deposited on the side surface and the bottom surface (i.e., the upper surface of the gate electrode 20) of the opening P. At this time, the fifth insulating film 85 deposited on the bottom surface of the opening P has a function of protecting the upper surface of the gate electrode 20 exposed inside the opening P by the isotropic etching.

Note that, as mentioned in the first embodiment as well, the filling state of the opening P with the fifth insulating film 85 and the covering state of the side surface of the opening P and the upper surface of the gate electrode 20, illustrated in FIG. 30, are merely examples, and do not limit the structure of the semiconductor device 10A according to the present embodiment.

### 3. Third Embodiment

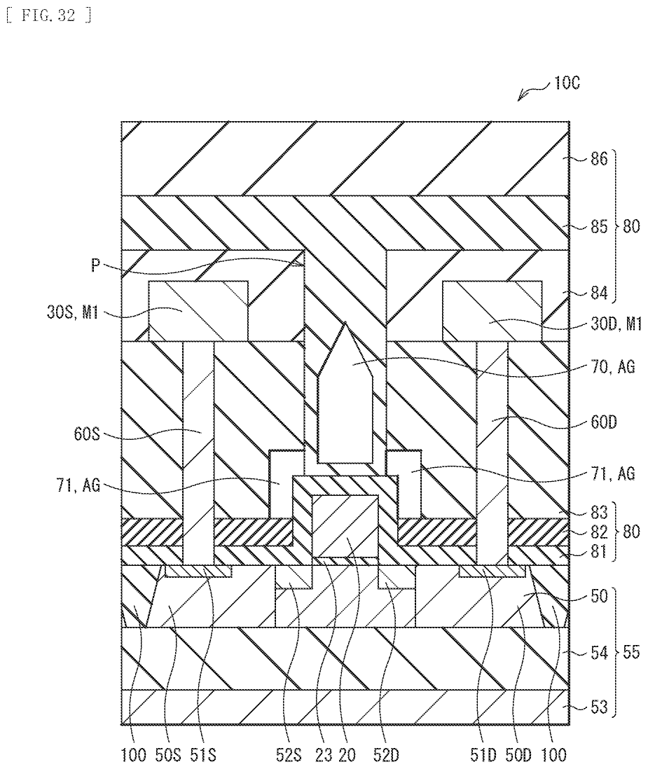

Now, referring to FIG. 31, a configuration of a semiconductor device according to a third embodiment of the present disclosure will be described. FIG. 31 is a longitudinal cross-sectional view of a cross-sectional configuration of a semiconductor device 10B according to the present embodiment. As with FIG. 7, FIG. 31 illustrates the cross-sectional configuration along line VII-VII in FIG. 6.

As illustrated in FIG. 31, in the semiconductor device 10B according to the present embodiment, the air gap AG serving as the second low-permittivity region 71 may be expanded than in the semiconductor device 10A illustrated in FIG. 30, while the width W70 of the air gap AG serving as the first low-permittivity region 70 is made substantially the same as in the semiconductor device 10 illustrated in FIG. 7.

Specifically, in the semiconductor device 10B, the opening P having a narrower opening width WP is formed, by narrowing an opening width of the low-permittivity-region-forming resist 65 used in forming the opening P. In addition, in the semiconductor device 10B, the range of the isotropic etching of the second opening 82 performed via the opening P is expanded to remove, in addition to the second semiconductor device 82, the first insulating film 81 covering the upper surface and the side surface of the gate electrode 20, and further the third insulating film 83 and the fourth insulating film 84 on the side surface of the opening P. This makes it possible to form the air gap AG in a wider range.

The isotropic etching of the first insulating film 81, the second insulating film 82, the third insulating film 83, and the fourth insulating film 84 via the opening P is performed for a long time to expand the air gap AG. Therefore, the opening width WP of the opening P widens between before and after the etching. In the semiconductor device 10B according to the present embodiment, the opening P is formed with the opening width WP narrowed in advance. This makes it possible to prevent the blockage of the upper portion of the opening P by the fifth insulating film 85 from becoming difficult by the opening width WP of the opening P excessively widening in the etching in forming the air gap AG.

Note that, in the semiconductor device 10B, the isotropic etching for formation of the air gap AG is performed by controlling an amount of etching to prevent the semiconductor layer 50 from being exposed. Specifically, the isotropic etching for formation of the air gap AG is performed by controlling the amount of etching to the extent that the first insulating film 81 provided on the upper surface of the semiconductor layer 50 does not disappear. One reason for this is that variations in gate length and threshold voltage can increase in a case where the semiconductor layer 50 in the vicinity of the gate insulating film 23 is exposed or the gate insulating film 23 is side-etched.

In the semiconductor device 10B, it is possible to form the air gap AG in a wider range by removing, in addition to the second semiconductor device 82, the first insulating film 81 covering the upper surface and the side surface of the gate electrode 20, and further the third insulating film 83 and the fourth insulating film 84 on the side surface of the opening P. Thus, the semiconductor device 10B makes it possible to further reduce the extrinsic component Cex of the off-capacitance, including the capacitance CgM between the gate electrode 20 and the contact plugs 60S and 60D or the first metals M1, the capacitance CMM1 generated between the first metals M1, and the like.

In the semiconductor device 10B according to the present embodiment, it is possible to reduce the film thickness of the fifth insulating film 85 deposited on the side surface and the bottom surface (i.e., the upper surface of the gate electrode 20) of the opening P, because the opening width WP of the opening P is substantially the same as in the semiconductor device 10 illustrated in FIG. 7. Thus, in the semiconductor device 10B, it is possible to suppress excessively filling of the air gaps AG serving as the first low-permittivity region 70 and the second low-permittivity region 71 by the fifth insulating film 85.

Note that, as mentioned in the first embodiment as well, the filling state of the opening P with the fifth insulating film 85 and the covering state of the side surface of the opening P and the upper surface of the gate electrode 20, illustrated in FIG. 31, are merely examples, and do not limit the structure of the semiconductor device 10B according to the present embodiment.

### 4. Fourth Embodiment

Next, referring to FIG. 32, a configuration of a semiconductor device according to a fourth embodiment of the present disclosure will be described. FIG. 32 is a longitudinal cross-sectional view of a cross-sectional configuration of a semiconductor device 10C according to the present embodiment. As with FIG. 7, FIG. 32 illustrates the cross-sectional configuration along line VII-VII in FIG. 6.

As illustrated in FIG. 32, the semiconductor device 10C according to the present embodiment differs from the semiconductor device 10 illustrated in FIG. 7 in that the first low-permittivity region 70 and the second low-permittivity region 71 are isolated from each other, without being spatially continuous, by a portion of the opening P being filled with the fifth insulating film 85.

Specifically, in the semiconductor device 10C, when forming the fifth insulating film 85 that blocks the upper portion of the opening P, the fifth insulating film 85 is deposited more inside the opening P by forming the fifth insulating film 85 by the CVD method under a condition where the opening P is highly fillable. Thus, in the semiconductor device 10C, the fifth insulating film 85 deposited on the side surface and the bottom surface (i.e., the upper surface of the first insulating film 81) of the opening P may be combined to isolate the first low-permittivity region 70 and the second low-permittivity region 71 from each other. Thus, the first low-permittivity region 70 is provided above the gate electrode 20, and the second low-permittivity region 71 is provided apart therefrom to surround the side surface of the gate electrode 20.

Therefore, even with the configuration of the semiconductor device 10C according to the present embodiment, the semiconductor device 10C makes it possible to, as with the semiconductor device 10 illustrated in FIG. 7, reduce the extrinsic component Cex of the off-capacitance, including the capacitance CgM between the gate electrode 20 and the contact plugs 60S and 60D or the first metals M1, the capacitance CMM1 generated between the first metals M1, and the like.

Note that, as mentioned in the first embodiment as well, the filling state of the opening P with the fifth insulating film 85 and the covering state of the side surface of the opening P and the upper surface of the first insulating film 81, illustrated in FIG. 32, are merely examples, and do not limit the structure of the semiconductor device 10C according to the present embodiment.

### 5. Fifth Embodiment

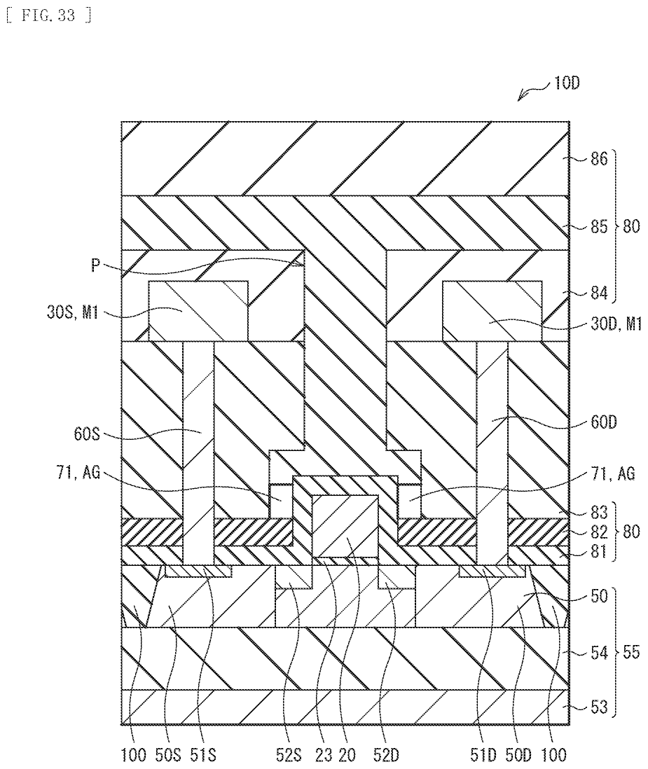

Now, referring to FIG. 33, a configuration of a semiconductor device according to a fifth embodiment of the present disclosure will be described. FIG. 33 is a longitudinal cross-sectional view of a cross-sectional configuration of a semiconductor device 10D according to the present embodiment. As with FIG. 7, FIG. 33 illustrates the cross-sectional configuration along line VII-VII in FIG. 6.

As illustrated in FIG. 33, the semiconductor device 10D according to the present embodiment differs from the semiconductor device 10 illustrated in FIG. 7 in that a region corresponding to the first low-permittivity region 70 is filled with the fifth insulating film 85 by the opening P being filled with the fifth insulating film 85.

Specifically, in the semiconductor device 10D, when forming the fifth opening 85 that blocks the upper portion of the opening P, a region, of the opening P, from the upper surface of the first insulating film 81 to an opening surface is filled with the fifth insulating film 85, by forming the fifth insulating film 85 by the CVD method under a condition where the opening P is highly fillable. Thus, the opening P below the lower surface of the first metal M1 and above the upper surface of the first insulating film 81 is filled with the fifth insulating film 85. However, it is possible to cause the above region to function as the first low-permittivity region 70, as in the semiconductor device 10 illustrated in FIG. 7, by forming the fifth insulating film 85 using a material with a lower relative permittivity than the third insulating film 83 and the fourth insulating film 84. Further, the second low-permittivity region 71 includes the air gap AG surrounding the side surface of the gate electrode 20.

Therefore, even with the configuration of the semiconductor device 10D according to the present embodiment, the semiconductor device 10D makes it possible to, as with the semiconductor device 10 illustrated in FIG. 7, reduce the extrinsic component Cex of the off-capacitance, including the capacitance CgM between the gate electrode 20 and the contact plugs 60S and 60D or the first metals M1, the capacitance CMM1 generated between the first metals M1, and the like.

Note that, as mentioned in the first embodiment as well, the filling state of the opening P with the fifth insulating film 85 illustrated in FIG. 33 is merely an example, and does not limit the structure of the semiconductor device 10D according to the present embodiment.

### 6. Sixth Embodiment

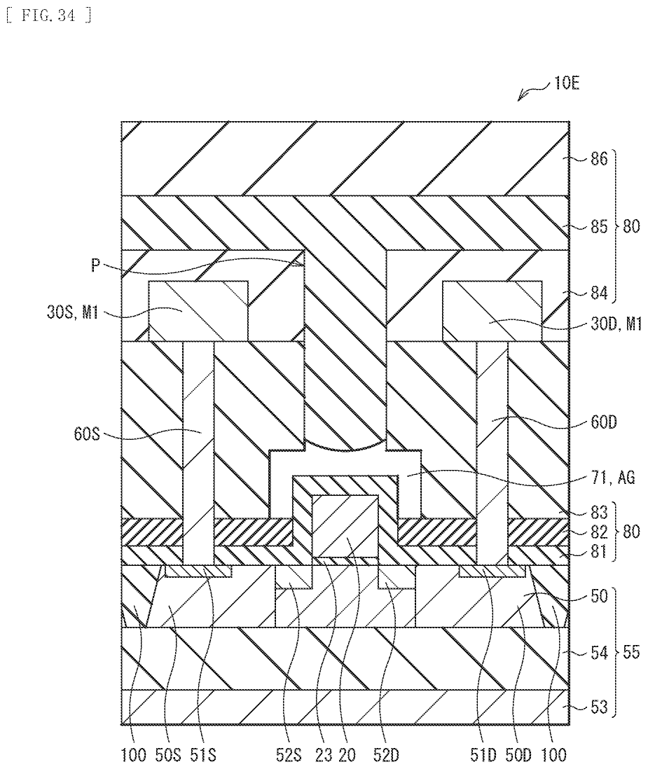

Next, referring to FIG. 34, a configuration of a semiconductor device according to a sixth embodiment of the present disclosure will be described. FIG. 34 is a longitudinal cross-sectional view of a cross-sectional configuration of a semiconductor device 10E according to the present embodiment. As with FIG. 7, FIG. 34 illustrates the cross-sectional configuration along line VII-VII in FIG. 6.

As illustrated in FIG. 34, the semiconductor device 10E according to the present embodiment differs from the semiconductor device 10D illustrated in FIG. 33 in that the fifth insulating film 85 is formed by applying a material having fluidity. Specifically, in the semiconductor device 10E, the upper portion of the opening P is blocked by forming the fifth insulating film 85 by applying an SOG (Spin On Glass) or organic resin film, which is a low dielectric film, or bonding an organic resin film. Because the SOG and the organic resin have high fluidity, it is possible to fill a region, of the opening P, from the opening surface to the upper surface of the first insulating film 81 with the fifth insulating film 85 more easily than by the CVD method.

Thus, the opening P below the lower surface of the first metal M1 and above the upper surface of the first insulating film 81 is filled with the fifth insulating film 85 including the SOG or the organic resin, which is a low dielectric film. Thus, it is able to function as the first low-permittivity region 70, as in the semiconductor device 10 illustrated in FIG. 7. Further, the second low-permittivity region 71 includes the air gap AG surrounding the side surface of the gate electrode 20.

Therefore, even with the configuration of the semiconductor device 10E according to the present embodiment, the semiconductor device 10E makes it possible to, as with the semiconductor device 10 illustrated in FIG. 7, reduce the extrinsic component Cex of the off-capacitance, including the capacitance CgM between the gate electrode 20 and the contact plugs 60S and 60D or the first metals M1, the capacitance CMM1 generated between the first metals M1, and the like.

Note that, as mentioned in the first embodiment as well, the filling state of the opening P with the fifth insulating film 85 illustrated in FIG. 34 is merely an example, and does not limit the structure of the semiconductor device 10E according to the present embodiment.

### 7. Seventh Embodiment

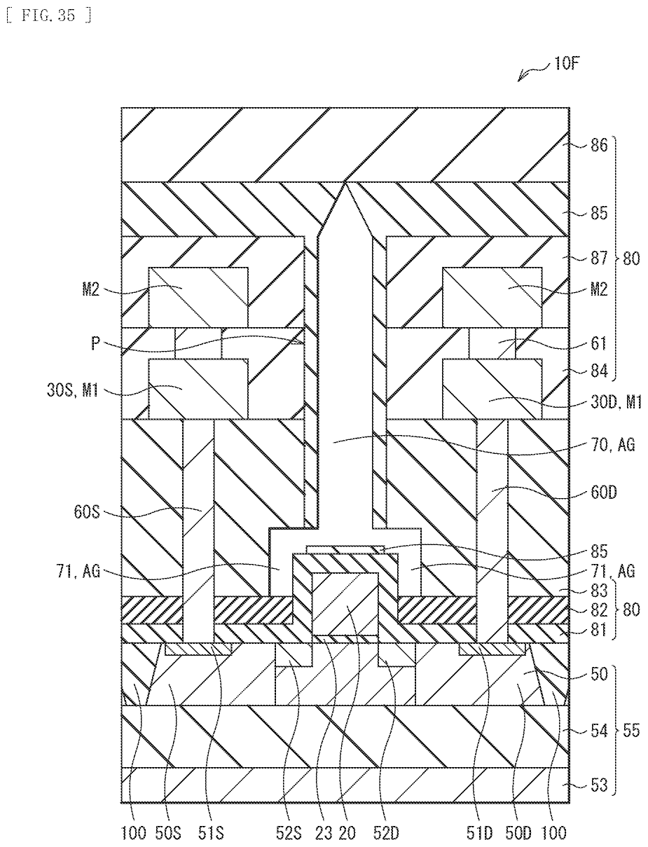

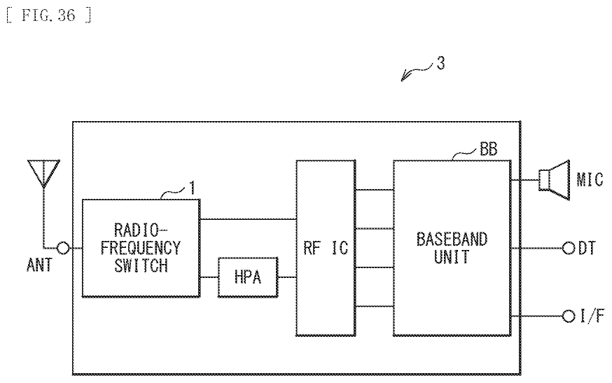

Now, referring to FIG. 35, a configuration of a semiconductor device according to a seventh embodiment of the present disclosure will be described. FIG. 35 is a longitudinal cross-sectional view of a cross-sectional configuration of a semiconductor device 10F according to the present embodiment. As with FIG. 7, FIG. 35 illustrates the cross-sectional configuration along line VII-VII in FIG. 6.

As illustrated in FIG. 35, the semiconductor device 10F according to the present embodiment differs from the semiconductor device 10 illustrated in FIG. 7 in that the second metal M2 provided between the fourth insulating film 84 and the fifth insulating film 85, and a seventh insulating film 87 covering a surface of the second metal M2 and the upper surface of the fourth insulating film 84 are further provided.

Specifically, in the semiconductor device 10F, the fourth insulating film 84 is provided to bury the first metal M1 and a contact plug 61 provided on the upper surface of the first metal M1. Further, the second metal M2 coupled to the first metal M1 via the contact plug 61 is provided on the fourth insulating film 84, and the seventh insulating film 87 is provided on the surface of the second metal M2 and the upper surface of the fourth insulating film. The opening P is formed from an upper surface of the seventh insulating film 87, and its upper portion is blocked by the fifth insulating film 85 provided on the seventh insulating film 87.

Materials included in the second metal M2, the seventh insulating film 87, and the contact plug 61 are substantially similar to those of the first metal M1, the fourth insulating film 84, and the contact plugs 60S and 60D, respectively, and description thereof will therefore be omitted.

In the semiconductor device 10F according to the present embodiment, it is possible to make the first low-permittivity region 70 including the air gap AG extend also between the second metals M2 provided on the first metals M1. Thus, the semiconductor device 10F makes it possible to reduce, in addition to the capacitance CgM between the gate electrode 20 and the contact plugs 60S and 60D or the first metals M1 and the capacitance CMM1 generated between the first metals M1, a capacitance Cg between the gate electrode 20 and the second metals M2 and a capacitance CMM2 generated between the second metals M2. Therefore, the semiconductor device 10F is able to reduce the extrinsic component Cex of the off-capacitance, including these capacitances.

Note that, as mentioned in the first embodiment as well, the filling state of the opening P with the fifth insulating film 85 and the covering state of the side surface of the opening P and the upper surface of the first insulating film 81, illustrated in FIG. 35, are merely examples, and do not limit the structure of the semiconductor device 10F according to the present embodiment.

### 8. Application Example

Further, referring to FIG. 36, description will be given on a configuration of a wireless communication apparatus that is an application example of the semiconductor devices according to the first to seventh embodiments of the present disclosure. FIG. 36 is a schematic diagram illustrating an example of a configuration of the wireless communication apparatus.

As illustrated in FIG. 36, a wireless communication apparatus 3 includes, for example, an antenna ANT, the radio-frequency switch 1, a high-power amplifier HPA, a radio frequency integrated circuit RFIC (Radio Frequency Integrated Circuit), a baseband unit BB, a voice output unit MIC, a data output unit DT, and an interface unit I/F (e.g., a wireless LAN (Wireless Local Area Network: W-LAN), Bluetooth (registered trademark), etc.). The wireless communication apparatus 3 is, for example, a radio-frequency module to be used in a mobile phone system having multiple functions, such as voice and data communication and LAN (Local Area Network) connection.

The radio-frequency switch 1 includes any of the semiconductor devices 10 and 10A to 10F according to the first to seventh embodiments.

In a case of outputting a transmission signal from a transmission system of the wireless communication apparatus 3 to the antenna ANT (i.e., in transmitting), the wireless communication apparatus 3 outputs the transmission signal outputted from the baseband unit BB to the antenna ANT via the radio-frequency integrated circuit RFIC, the high-power amplifier HPA, and the radio-frequency switch 1.

On the other hand, in a case of inputting a received signal received by the antenna ANT to a reception system of the wireless communication apparatus 3 (i.e., in receiving), the wireless communication apparatus 3 inputs the received signal to the baseband unit BB via the radio-frequency switch 1 and the radio-frequency integrated circuit RFIC. The received signal processed by the baseband unit BB is outputted from an output unit, such as the voice output unit MIC, the data output unit DT, or the interface unit I/F.

Although the technology according to the present disclosure has been described above with reference to the first to seventh embodiments, the technology according to the present disclosure is not limited to the above embodiments, and various modifications may be made.

For example, although the above embodiments assume that the first conductivity-type impurity is an n-type impurity, such as arsenic (As) or phosphorus (P), and the second conductivity-type impurity is a p-type impurity, such as boron (B) or aluminum (Al), these conductivity types may be reversed. That is, the first conductivity-type impurity may be a p-type impurity, such as boron (B) or aluminum (Al), and the second conductivity-type impurity may be an n-type impurity, such as arsenic (As) or phosphorus (P).

For example, the above embodiments specifically describe, as embodiments of the technology according to the present disclosure, the configurations of the radio-frequency switch 1, the semiconductor device 10, such as a field-effect transistor, and the wireless communication apparatus 3. However, these configurations are not limited to those including all of the illustrated components, and it is also possible to replace some of the components with other components.

Further, although the above embodiments describe an example of applying the semiconductor device 10 to the radio-frequency switch 1 of the wireless communication apparatus 3, the semiconductor device 10 is also applicable to another radio-frequency device, such as a PA (Power Amplifier), in addition to a radio-frequency switch (RF-SW).

Furthermore, the shape, material, and thickness or the film-forming method etc. of each layer described in the above embodiments are not limited to the above, and may be another shape, material, and thickness, or may be another film-forming method.

Not all of the configurations and operations described in the embodiments are necessary as the configurations and operations of the present disclosure. For example, among components in the embodiments, the component that is not described in the independent claim reciting the most generic concept of the present disclosure should be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”. Further, it will be apparent to those skilled in the art that modifications may be made to the embodiments of the present disclosure without departing from the scope of the appended claims.

Terms used in this specification include terms that are used for convenience in description only and do not limit configurations and operations. For example, terms such as “right”, “left”, “on”, and “under” only indicate directions on the drawing being referred to. Further, the terms “inside” and “outside” indicate, respectively, a direction toward the center of a component of interest and a direction away from the center of a component of interest. The same applies to terms similar to these and to terms with the same purpose.

It is to be noted that the technology according to the present disclosure may have the following configurations. According to the technology according to the present disclosure having the following configurations, it is possible to reduce off-capacitance of a field-effect transistor. Effects of the technology according to the present disclosure are not necessarily limited to the effects described herein, and may be any of the effects described in the present disclosure.

(1)

A semiconductor device including:

a gate electrode;

a semiconductor layer including a source region and a drain region provided with the gate electrode in between;

contact plugs provided on the source region and the drain region;

first metals stacked on the respective contact plugs;

a first low-permittivity region provided in at least any region that is between the first metals in an in-plane direction of the semiconductor layer and below a lower surface of the first metal in a stacking direction of the semiconductor layer; and

a second low-permittivity region provided in at least any region that is between the contact plug and the gate electrode in the in-plane direction and below the first low-permittivity region in the stacking direction,

in which the second low-permittivity region is provided in a planar region that is at least partially different from a planar region provided with the first low-permittivity region.

(2)

The semiconductor device according to (1), in which the first low-permittivity region is provided to further extend to at least any region between an upper surface and the lower surface of the first metal in the stacking direction.

(3)

The semiconductor device according to (2), in which the first low-permittivity region is provided to further extend to at least any region above the upper surface of the first metal in the stacking direction.

(4)

The semiconductor device according to any one of (1) to (3), in which the second low-permittivity region is provided to be continuous with the first low-permittivity region.

(5)

The semiconductor device according to (4), in which

the first low-permittivity region and the second low-permittivity region each include an air gap, and

the air gap included in the first low-permittivity region and the air gap included in the second low-permittivity region are provided to be continuous with each other.

(6)

The semiconductor device according to any one of (1) to (5), further including:

one or more insulating films provided on the semiconductor layer to cover the gate electrode; and

an opening provided in a planar region corresponding to the gate electrode, from an upper surface of the one or more insulating films, in which

the first low-permittivity region is provided inside the opening.

(7)

The semiconductor device according to (6), in which the one or more insulating films include insulating films including materials having different etching rates.

(8)

The semiconductor device according to (7), in which

the one or more insulating films include
a first insulating film covering a surface of the gate electrode and a surface of the semiconductor layer,
a second insulating film covering a surface of the first insulating film, and
a third insulating film provided between a surface of the second insulating film and the lower surface of the first metal, and

the first insulating film includes a material having a different etching rate from a material of the second insulating film.

(9)

The semiconductor device according to (8), in which, in one cross-section in the stacking direction, the first low-permittivity region has a width that is smaller than a width of the first insulating film provided on the surface of the gate electrode.

(10)

The semiconductor device according to (8) or (9), in which the opening is provided to penetrate at least the third insulating film on the gate electrode.

(11)

The semiconductor device according to (10), in which the opening is provided to further penetrate the second insulating film, or the second insulating film and the first insulating film, on the gate electrode.

(12)

The semiconductor device according to (10) or (11), in which

the one or more insulating films further include a fourth insulating film covering an upper surface of the third insulating film and a surface of the first metal, and

the opening is provided from an upper surface of the fourth insulating film.

(13)

The semiconductor device according to (12), in which

the one or more insulating films further include a fifth insulating film provided on the fourth insulating film, and

the fifth insulating film blocks an upper portion of the opening.

(14)

The semiconductor device according to (13), further including a second metal provided between the fourth insulating film and the fifth insulating film, in which

the one or more insulating films further include a seventh insulating film covering the upper surface of the fourth insulating film and a surface of the second metal, and

the opening is provided from an upper surface of the seventh insulating film.

(15)

The semiconductor device according to (13) or (14), in which the fifth insulating film covers at least a portion of a side surface of the opening.

(16)

The semiconductor device according to any one of (13) to (15), in which

the fifth insulating film includes a material having a lower permittivity than a material included in the third insulating film and the fourth insulating film, and

the first low-permittivity region includes at least a portion of the opening filled with the fifth insulating film.

(17)

The semiconductor device according to (6), in which

the one or more insulating films include
a first insulating film covering a surface of the gate electrode and a surface of the semiconductor layer,
a second insulating film covering a surface of the first insulating film,
a third insulating film provided between a surface of the second insulating film and the lower surface of the first metal,
a fourth insulating film covering an upper surface of the third insulating film and a surface of the first metal, and
a fifth insulating film provided on the fourth insulating film and blocking the opening, and

the second low-permittivity region includes, in the stacking direction, an air gap provided in a region provided with at least any of the first insulating film, the second insulating film, and the third insulating film.

(18)

The semiconductor device according to (17), in which the air gap included in the second low-permittivity region exposes at least a portion of the first insulating film.

(19)

The semiconductor device according to (18), in which the air gap included in the second low-permittivity region exposes the first insulating film provided on the surface of the semiconductor layer.

(20)

The semiconductor device according to (19), in which the air gap included in the second low-permittivity region further exposes at least a portion of the gate electrode.

(21)

The semiconductor device according to any one of (17) to (20), in which the air gap included in the second low-permittivity region is provided to be continuous with the opening provided from an upper surface of the fourth insulating film to penetrate at least the third insulating film on the gate electrode.

(22)

The semiconductor device according to (21), in which the fifth insulating film covers at least a portion of a side surface or a bottom surface of the air gap included in the second low-permittivity region.

(23)

The semiconductor device according to any one of (17) to (22), in which, in one cross-section in the stacking direction, a region provided with the second low-permittivity region has a width that is larger than a width of the first insulating film provided on the surface of the gate electrode.

(24)

The semiconductor device according to any one of (17) to (23), in which

the fifth insulating film includes a material having a lower permittivity than a material included in the third insulating film and the fourth insulating film, and

the second low-permittivity region includes a region filled with the fifth insulating film.

(25)

The semiconductor device according to any one of (1) to (24), in which

the gate electrode is provided to extend in one direction in the in-plane direction, and

the contact plug, the first metal, the first low-permittivity region, and the second low-permittivity region are provided to extend in a direction parallel to the extending direction of the gate electrode in the in-plane direction.

(26)

The semiconductor device according to (25), in which the first low-permittivity region and the second low-permittivity region are provided to extend in a direction intersecting the extending direction of the gate electrode in the in-plane direction.

(27)

The semiconductor device according to any one of (1) to (26), in which

the gate electrode includes a plurality of finger parts extending in a same direction and a linking part linking the plurality of finger parts,

the first low-permittivity region is provided above the finger part or above at least a portion of the linking part, and

the second low-permittivity region is provided on a sidewall of the finger part or a sidewall of at least a portion of the linking part.

(28)

The semiconductor device according to any one claims 1 of (1) to (27), in which

the semiconductor device is provided with, in the in-plane direction,
a device region including the source region and the drain region, and
a wiring region including a multilayer wiring part and separated from the device region by a device isolation layer, and

the first low-permittivity region and the second low-permittivity region are provided in the device region.

(29)

The semiconductor device according to (28), in which
the semiconductor device is provided with, in the in-plane direction,
   an active region including the device region and the wiring region, and
   a device isolation region including the device isolation layer and provided outside the active region,
a gate contact coupled to the gate electrode is provided on the device isolation layer of the device isolation region, and
the first low-permittivity region and the second low-permittivity region are provided to avoid the gate contact.

(30)

The semiconductor device according to any one of (1) to (29), in which the semiconductor device is used as a field-effect transistor for a radio-frequency device.

(31)

A method of manufacturing a semiconductor device, the method including:

a step of forming a gate electrode on an upper surface side of a semiconductor layer;

a step of forming, in the semiconductor layer, a source region and a drain region with the gate electrode in between;

a step of forming contact plugs on the source region and the drain region;

a step of stacking first metals on the respective contact plugs;

a step of forming a first low-permittivity region in at least any region that is between the first metals in an in-plane direction of the semiconductor layer and below a lower surface of the first metal in a stacking direction of the semiconductor layer; and

a step of forming a second low-permittivity region in at least any region that is between the contact plug and the gate electrode in the in-plane direction and below the first low-permittivity region in the stacking direction,

in which the second low-permittivity region is formed in a planar region that is at least partially different from a planar region in which the first low-permittivity region is formed.

This application claims the benefit of Japanese Priority Patent Application No. 2019-114339 filed with the Japan Patent Office on Jun. 20, 2019, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a gate electrode;
a semiconductor layer including a source region and a drain region provided with the gate electrode in between;
contact plugs provided on the source region and the drain region;
first metals stacked on the respective contact plugs;
a first low-permittivity region provided in at least any region that is between the first metals in an in-plane direction of the semiconductor layer and below a lower surface of the first metal in a stacking direction of the semiconductor layer; and
a second low-permittivity region provided in at least any region that is between the contact plug and the gate electrode in the in-plane direction and below the first low-permittivity region in the stacking direction,
wherein the second low-permittivity region is provided in a planar region that is at least partially different from a planar region provided with the first low-permittivity region.

2. The semiconductor device according to claim 1, wherein the first low-permittivity region is provided to further extend to at least any region between an upper surface and the lower surface of the first metal in the stacking direction.

3. The semiconductor device according to claim 2, wherein the first low-permittivity region is provided to further extend to at least any region above the upper surface of the first metal in the stacking direction.

4. The semiconductor device according to claim 1, wherein the second low-permittivity region is provided to be continuous with the first low-permittivity region.

5. The semiconductor device according to claim 4, wherein
the first low-permittivity region and the second low-permittivity region each include an air gap, and
the air gap included in the first low-permittivity region and the air gap included in the second low-permittivity region are provided to be continuous with each other.

6. The semiconductor device according to claim 1, further comprising:
one or more insulating films provided on the semiconductor layer to cover the gate electrode; and
an opening provided in a planar region corresponding to the gate electrode, from an upper surface of the one or more insulating films, wherein
the first low-permittivity region is provided inside the opening.

7. The semiconductor device according to claim 6, wherein the one or more insulating films include insulating films including materials having different etching rates.

8. The semiconductor device according to claim 7, wherein
the one or more insulating films include
a first insulating film covering a surface of the gate electrode and a surface of the semiconductor layer,
a second insulating film covering a surface of the first insulating film, and
a third insulating film provided between a surface of the second insulating film and the lower surface of the first metal, and
the first insulating film includes a material having a different etching rate from a material of the second insulating film.

9. The semiconductor device according to claim 8, wherein, in one cross-section in the stacking direction, the first low-permittivity region has a width that is smaller than a width of the first insulating film provided on the surface of the gate electrode.

10. The semiconductor device according to claim 8, wherein the opening is provided to penetrate at least the third insulating film on the gate electrode.

11. The semiconductor device according to claim 10, wherein the opening is provided to further penetrate the second insulating film, or the second insulating film and the first insulating film, on the gate electrode.

12. The semiconductor device according to claim 10, wherein
the one or more insulating films further include a fourth insulating film covering an upper surface of the third insulating film and a surface of the first metal, and
the opening is provided from an upper surface of the fourth insulating film.

13. The semiconductor device according to claim 12, wherein
the one or more insulating films further include a fifth insulating film provided on the fourth insulating film, and
the fifth insulating film blocks an upper portion of the opening.

14. The semiconductor device according to claim 13, further comprising a second metal provided between the fourth insulating film and the fifth insulating film, wherein
the one or more insulating films further include a seventh insulating film covering the upper surface of the fourth insulating film and a surface of the second metal, and
the opening is provided from an upper surface of the seventh insulating film.

15. The semiconductor device according to claim 13, wherein the fifth insulating film covers at least a portion of a side surface of the opening.

16. The semiconductor device according to claim 13, wherein
the fifth insulating film includes a material having a lower permittivity than a material included in the third insulating film and the fourth insulating film, and
the first low-permittivity region includes at least a portion of the opening filled with the fifth insulating film.

17. The semiconductor device according to claim 6, wherein
the one or more insulating films include
a first insulating film covering a surface of the gate electrode and a surface of the semiconductor layer,
a second insulating film covering a surface of the first insulating film,
a third insulating film provided between a surface of the second insulating film and the lower surface of the first metal,
a fourth insulating film covering an upper surface of the third insulating film and a surface of the first metal, and
a fifth insulating film provided on the fourth insulating film and blocking the opening, and
the second low-permittivity region includes, in the stacking direction, an air gap provided in a region provided with at least any of the first insulating film, the second insulating film, and the third insulating film.

18. The semiconductor device according to claim 17, wherein the air gap included in the second low-permittivity region exposes at least a portion of the first insulating film.

19. The semiconductor device according to claim 18, wherein the air gap included in the second low-permittivity region exposes the first insulating film provided on the surface of the semiconductor layer.

20. The semiconductor device according to claim 19, wherein the air gap included in the second low-permittivity region further exposes at least a portion of the gate electrode.

21. The semiconductor device according to claim 17, wherein the air gap included in the second low-permittivity region is provided to be continuous with the opening provided from an upper surface of the fourth insulating film to penetrate at least the third insulating film on the gate electrode.

22. The semiconductor device according to claim 21, wherein the fifth insulating film covers at least a portion of a side surface or a bottom surface of the air gap included in the second low-permittivity region.

23. The semiconductor device according to claim 17, wherein, in one cross-section in the stacking direction, a region provided with the second low-permittivity region has a width that is larger than a width of the first insulating film provided on the surface of the gate electrode.

24. The semiconductor device according to claim 17, wherein
the fifth insulating film includes a material having a lower permittivity than a material included in the third insulating film and the fourth insulating film, and
the second low-permittivity region includes a region filled with the fifth insulating film.

25. The semiconductor device according to claim 1, wherein
the gate electrode is provided to extend in one direction in the in-plane direction, and
the contact plug, the first metal, the first low-permittivity region, and the second low-permittivity region are provided to extend in a direction parallel to the extending direction of the gate electrode in the in-plane direction.

26. The semiconductor device according to claim 25, wherein the first low-permittivity region and the second low-permittivity region are provided to extend in a direction intersecting the extending direction of the gate electrode in the in-plane direction.

27. The semiconductor device according to claim 1, wherein
the gate electrode includes a plurality of finger parts extending in a same direction and a linking part linking the plurality of finger parts,
the first low-permittivity region is provided above the finger part or above at least a portion of the linking part, and
the second low-permittivity region is provided on a sidewall of the finger part or a sidewall of at least a portion of the linking part.

28. The semiconductor device according to claim 1, wherein
the semiconductor device is provided with, in the in-plane direction,
a device region including the source region and the drain region, and
a wiring region including a multilayer wiring part and separated from the device region by a device isolation layer, and
the first low-permittivity region and the second low-permittivity region are provided in the device region.

29. The semiconductor device according to claim 28, wherein
the semiconductor device is provided with, in the in-plane direction,
an active region including the device region and the wiring region, and
a device isolation region including the device isolation layer and provided outside the active region,
a gate contact coupled to the gate electrode is provided on the device isolation layer of the device isolation region, and
the first low-permittivity region and the second low-permittivity region are provided to avoid the gate contact.

30. The semiconductor device according to claim 1, wherein the semiconductor device is used as a field-effect transistor for a radio-frequency device.

31. A method of manufacturing a semiconductor device, the method comprising:
a step of forming a gate electrode on an upper surface side of a semiconductor layer;
a step of forming, in the semiconductor layer, a source region and a drain region with the gate electrode in between;
a step of forming contact plugs on the source region and the drain region;
a step of stacking first metals on the respective contact plugs;
a step of forming a first low-permittivity region in at least any region that is between the first metals in an in-plane direction of the semiconductor layer and below a lower surface of the first metal in a stacking direction of the semiconductor layer; and
a step of forming a second low-permittivity region in at least any region that is between the contact plug and the gate electrode in the in-plane direction and below the first low-permittivity region in the stacking direction,
wherein the second low-permittivity region is formed in a planar region that is at least partially different from a planar region in which the first low-permittivity region is formed.
